(19) United States
(12) Patent Application Publication
(10) Pub. No.: US 2024/0178236 A1
(43) Pub. Date: May 30, 2024

(54) DISPLAY DEVICE AND MANUFACTURING METHOD OF DISPLAY DEVICE

(71) Applicant: Sharp Display Technology Corporation, Kameyama City (JP)

(72) Inventors: Yuhichi SAITOH, Kameyama City (JP); Atsushi HACHIYA, Kameyama City (JP); Hiroaki FURUKAWA, Kameyama City (JP)

(21) Appl. No.: 18/378,832

(22) Filed: Oct. 11, 2023

(30) Foreign Application Priority Data
Nov. 28, 2022 (JP) 2022-189375

(51) Int. Cl. H01L 27/12; G02F 1/1362; G02F 1/1368; G02F 1/1343

(52) U.S. Cl. CPC H01L 27/124; G02F 1/136231; G02F 1/13685; H01L 27/1288; G02F 1/134318; G02F 1/134363; G02F 1/136227; H01L 27/1225

(57) ABSTRACT

A display device includes a first semiconductor portion, a first insulating film, a first electrode, a second electrode, a second insulating film, a second semiconductor portion, a third insulating film, a third electrode, and a fourth electrode, the second insulating film is disposed to overlap at least the second semiconductor portion and is not formed in a range overlapping the first semiconductor portion, the first insulating film and the third insulating film are each provided with a first contact hole connecting the third electrode to the first semiconductor portion, and the third insulating film is provided with a second contact hole connecting the fourth electrode to the second semiconductor portion.

### CROSS-REFERENCE TO RELATED APPLICATIONS

This application claims the benefit of priority to Japanese Patent Application Number 2022-189375 filed on Nov. 28, 2022. The entire contents of the above-identified application are hereby incorporated by reference.

### BACKGROUND

### Technical Field

The technology disclosed herein relates to a display device and a manufacturing method of the display device.

In the related art, as an example of a display device, there is known display devices described in JP 2014-149410 A and JP 2022-522556 T. The display device described in JP 2014-149410 A includes a thin film transistor array substrate including thin film transistors formed on a substrate. The thin film transistor array substrate includes a gate electrode and a gate wiring line connected to the gate electrode formed on the substrate, a gate insulating film covering the gate electrode and the gate wiring line, a semiconductor film formed on the gate insulating film, a source electrode and a drain electrode formed on the semiconductor film above the gate electrode, a source wiring line formed on the semiconductor film and connected to the source electrode, a pixel electrode formed directly layered on the drain electrode, an interlayer insulating film covering the source electrode, the drain electrode, the source wiring line, and the pixel electrode, and a counter electrode disposed opposite to the pixel electrode via the interlayer insulating film. The semiconductor film is patterned in the same manner as the source electrode, the drain electrode, and the source wiring line except for a region between the source electrode and the drain electrode, and the gate insulating film includes a thin film portion thinner than other portions in a region in contact with the interlayer insulating film. In manufacturing the thin film transistor array substrate, an etching step of patterning a first transparent conductive film to form the pixel electrode and an etching step of etching a metal film to form the source electrode and the drain electrode and to expose the semiconductor film to be a channel region of the TFT are separately performed. In the etching step of forming the pixel electrode, dry etching is also performed in which the metal film, an ohmic contact film, and the semiconductor film of a pattern remaining portion exposed from below the first transparent conductive film, can be removed. At this time, an upper surface of a portion of the exposed gate insulating film is scraped to form the thin film portion.

The display device described in JP 2022-522556 T includes a first metal layer including a first gate, a second metal layer including a first source, a first drain, and a second gate, a polysilicon semiconductor layer including both ends electrically connected to the first source and the first drain, respectively, a third metal layer including a second source and a second drain, and a metal oxide semiconductor layer including both ends electrically connected to the second source and the second drain, respectively.

### SUMMARY

In the display device described in the above-described JP 2022-522556 T, a first source and a first drain connected to a polysilicon semiconductor layer are made of a second metal layer, and a second source and a second drain connected to a metal oxide semiconductor layer are made of a third metal layer. Thus, a step of forming a first contact hole in a first insulating layer and a gate insulating layer each located between the polysilicon semiconductor layer and the second metal layer, and a step of forming a second contact hole in a second insulating layer and a third insulating layer each located between the metal oxide semiconductor layer and the third metal layer are required. Thus, a problem is long tact. In addition, it is necessary to prepare a photomask for patterning the first insulating layer and the gate insulating layer and a photomask for patterning the second insulating layer and the third insulating layer. These problems are difficult to be solved even when the technology described in JP 2014-149410 A is applied to JP 2022-522556 T.

The technology disclosed herein have been made based on the circumstances described above, and an object thereof is to shorten tact.
(1) A display device according to a technology disclosed herein includes a first semiconductor portion made of a first semiconductor film, a first insulating film disposed on an upper-layer side of the first semiconductor film, a first electrode made of a first conductive film disposed on an upper-layer side of the first insulating film and disposed to overlap a part of the first semiconductor portion, a second electrode made of a part of the first conductive film, the part being different from the first electrode, a second insulating film disposed on an upper-layer side of the first conductive film, a second semiconductor portion made of a second semiconductor film disposed on an upper-layer side of the second insulating film, including a part disposed to overlap the second electrode, a third insulating film disposed on an upper-layer side than the second semiconductor film, a third electrode made of a second conductive film disposed on an upper-layer side of the third insulating film and disposed at a position overlapping the first semiconductor portion and not overlapping the first electrode, and a fourth electrode made of a part of the second conductive film, the part being different from the third electrode, and disposed to overlap a part of the second semiconductor portion. The second insulating film is disposed to overlap at least the second semiconductor portion and is not formed in a range overlapping the first semiconductor portion, a first contact hole connecting the third electrode to the first semiconductor portion is provided in the first insulating film and the third insulating film at a position overlapping the first semiconductor portion and the third electrode, and a second contact hole connecting the fourth electrode to the second semiconductor portion is provided in the third insulating film at a position overlapping the second semiconductor portion and the fourth electrode.
(2) In addition to (1), the display device may further include a fourth insulating film disposed on an upper-layer side of the second semiconductor film and on a lower-layer side than the third insulating film, and a fifth electrode made of a third conductive film disposed on an upper-layer side of the fourth insulating film and on a lower-layer side of the third insulating film and disposed to overlap a part of the second semiconductor portion. The fifth electrode may be connected to the second electrode.
(3) In addition to (2), in the display device, the fourth insulating film may be disposed to overlap at least each of the first semiconductor portion and the second semiconductor portion, and a part of the first contact hole and a part of the second contact hole may be provided in the fourth insulating film.
(4) In addition to (2), in the display device, the fourth insulating film may be disposed to overlap the fifth electrode or the second semiconductor portion.
(5) In addition to (4), in the display device, the fourth insulating film may be disposed to overlap the fifth electrode.
(6) In addition to (4), in the display device, the fourth insulating film may be disposed to overlap the second semiconductor portion, and a part of the second contact hole may be provided in the fourth insulating film at a position overlapping the second semiconductor portion.
(7) In addition to any one of (1) to (6), the display device may include a pixel electrode, a display region, the pixel electrode being disposed and an image being displayed in the display region, a sixth electrode disposed in the display region and connected to the pixel electrode, a first wiring line disposed in the display region, a second wiring line disposed in the display region, and a circuit portion supplying a signal to at least one of the first wiring line and the second wiring line. The first semiconductor film may be made of a polysilicon semiconductor material, the second semiconductor film may be made of an oxide semiconductor material, the first semiconductor portion, the first electrode, and the third electrode may be disposed in the circuit portion, the second semiconductor portion, the second electrode, and the fourth electrode may be disposed in the display region, the second electrode may be connected to the first wiring line, the fourth electrode may be connected to the second wiring line, and the sixth electrode may be connected to the second semiconductor portion.
(8) A display device according to a technology disclosed herein includes a first semiconductor portion made of a first semiconductor film, a first insulating film disposed on an upper-layer side of the first semiconductor film, a first electrode made of a first conductive film disposed on an upper-layer side of the first insulating film and disposed to overlap a part of the first semiconductor portion, a second insulating film disposed on an upper-layer side of the first conductive film, a second semiconductor portion made of a second semiconductor film disposed on an upper-layer side of the second insulating film, a third insulating film disposed on an upper-layer side of the second semiconductor film, a second electrode made of a second conductive film disposed on an upper-layer side of the third insulating film and disposed to overlap a part of the second semiconductor portion, a fourth insulating film disposed on an upper-layer side of the second conductive film, a third electrode made of a third conductive film disposed on an upper-layer side of the fourth insulating film and disposed at a position overlapping the first semiconductor portion and not overlapping the first electrode, and a fourth electrode made of a part of the third conductive film different from the third electrode and disposed at a position overlapping the second semiconductor portion and not overlapping the second electrode. The second insulating film is disposed to overlap at least the second semiconductor portion and is not formed in a range overlapping the first semiconductor portion, the third insulating film is disposed to overlap at least the second electrode, a first contact hole connecting the third electrode to the first semiconductor portion is provided in the first insulating film and the third insulating film at a position overlapping the first semiconductor portion and the fourth electrode, and a second contact hole connecting the fourth electrode to the second semiconductor portion is provided in the fourth insulating film at a position overlapping the second semiconductor portion and the fourth electrode.
(9) A manufacturing method of a display device according to a technology disclosed herein includes performing film formation of a first semiconductor film and patterning the first semiconductor film to provide a first semiconductor portion, performing film formation of a first insulating film on an upper-layer side of the first semiconductor film, performing film formation of a first conductive film on an upper-layer side of the first insulating film and patterning the first conductive film to provide a first electrode and a second electrode disposed to overlap a part of the first semiconductor portion, performing film formation of a second insulating film on an upper-layer side of the first conductive film, performing film formation of a second semiconductor film on an upper-layer side of the second insulating film and patterning the second semiconductor film to provide a second semiconductor portion including a part disposed to overlap the second electrode, patterning the second insulating film to overlap at least the second semiconductor portion and not being formed in a range overlapping the first semiconductor portion, performing film formation of a third insulating film on an upper-layer side than the second semiconductor film and patterning the third insulating film to provide a part of a first contact hole at a position overlapping a part of the first semiconductor portion and not overlapping the first electrode and to provide a second contact hole at a position overlapping a part of the second semiconductor portion, patterning the first insulating film subsequent to the third insulating film to provide a part of the first contact hole at a position overlapping a part of the first semiconductor portion and not overlapping the first electrode, and performing film formation of a second conductive film on an upper-layer side of the third insulating film and patterning the second conductive film to provide a third electrode disposed to overlap the first contact hole and connected to the first semiconductor portion through the first contact hole and a fourth electrode disposed to overlap the second contact hole and connected to the second semiconductor portion through the second contact hole.
(10) In addition to (9), in the manufacturing method of a display device, in patterning the second semiconductor film, film formation of a first photoresist film may be performed on an upper-layer side of the second semiconductor film, the first photoresist film may be exposed and developed, and then the second semiconductor film may be etched using the first photoresist film as a mask to provide the second semiconductor portion, and in patterning the second insulating film, the second insulating film may be etched using the first photoresist film as a mask.
(11) In addition to (10), in the manufacturing method of a display device, in patterning the second semiconductor film, the second semiconductor film may be wet etched, and in patterning the second insulating film, the second insulating film may be dry etched.
(12) In addition to (10) or (11), in the manufacturing method of a display device, in patterning the second insulating film, an etching rate of the second insulating film may be set higher than an etching rate of the first insulating film.
(13) In addition to any one of (10) to (12), in the manufacturing method of a display device, in performing film formation of the second insulating film, film formation of a lower layer film made of the same material as the first insulating film may be performed on an upper-layer side of the first conductive film, and film formation of an upper layer film may be performed on an upper-layer side of the lower layer film to provide the second insulating film having a layered structure.
(14) In addition to any one of (9) to (13), in the manufacturing method of a display device, before performing film formation of the third insulating film, film formation of a fourth insulating film may be performed on an upper-layer side of the second semiconductor film, film formation of a third conductive film may be performed on an upper-layer side of the fourth insulating film, and the third conductive film may be patterned to provide a fifth electrode disposed to overlap a part of the second semiconductor portion, in patterning the third conductive film, film formation of a second photoresist film may be performed on an upper-layer side of the third conductive film, the second photoresist film may be exposed and developed, and then the third conductive film may be etched using the second photoresist film as a mask to provide the fifth electrode, and in patterning the fourth insulating film, the fourth insulating film may be etched using the second photoresist film as a mask.
(15) In addition to any one of (9) to (13), in the manufacturing method of a display device, before performing film formation of the third insulating film, film formation of a fourth insulating film may be performed on an upper-layer side of the second semiconductor film, film formation of a third conductive film may be performed on an upper-layer side of the fourth insulating film, and the third conductive film may be patterned to provide a fifth electrode disposed to overlap a part of the second semiconductor portion, in patterning the second semiconductor film, film formation of a first photoresist film may be performed on an upper-layer side of the second semiconductor film, the first photoresist film may be exposed through a first photomask, and then the first photoresist film may be developed, and the second semiconductor film may be etched using the first photoresist film as a mask to provide the second semiconductor portion, and in patterning the fourth insulating film, film formation of a third photoresist film may be performed on an upper-layer side of the fourth insulating film, the third photoresist film may be exposed through a second photomask having the same pattern as a pattern of the first photomask, and then the third photoresist film may be developed, and the fourth insulating film may be etched using the third photoresist film as a mask.

According to the technology disclosed herein, tact can be shortened.

### BRIEF DESCRIPTION OF DRAWINGS

The disclosure will be described with reference to the accompanying drawings, wherein like numbers reference like elements.

FIG. 1 is a schematic perspective view illustrating a state in which a head-mounted display according to a first embodiment is worn on a head by a user.

FIG. 2 is a schematic side view illustrating an optical relationship between a liquid crystal display device and a lens unit provided in a head-mounted device included in the head-mounted display according to the first embodiment, and an eyeball of the user.

FIG. 3 is a schematic plan view illustrating a liquid crystal panel and a flexible substrate provided in the liquid crystal display device according to the first embodiment.

FIG. 4 is a schematic cross-sectional view of the liquid crystal panel according to the first embodiment.

FIG. 5 is a circuit diagram illustrating a pixel arrangement in a display region of an array substrate provided in the liquid crystal panel according to the first embodiment.

FIG. 6 is a cross-sectional view of a first TFT and a second TFT provided in the array substrate according to the first embodiment.

FIG. 7 is a cross-sectional view of a first TFT and a second TFT provided in an array substrate of a comparative example according to the first embodiment.

FIG. 8 is a cross-sectional view of the first TFT and the second TFT illustrating a state in which a first photoresist film is developed in a sixth step included in an array substrate manufacturing step according to the first embodiment.

FIG. 9 is a cross-sectional view of the first TFT and the second TFT illustrating a state in which a second semiconductor film is wet etched in the sixth step included in the array substrate manufacturing step according to the first embodiment.

FIG. 10 is a cross-sectional view of the first TFT and the second TFT illustrating a state in which a second insulating film is dry etched in the sixth step included in the array substrate manufacturing step according to the first embodiment.

FIG. 11 is a cross-sectional view of the first TFT and the second TFT illustrating a state in which a second photoresist film is developed in a ninth step included in the array substrate manufacturing step according to the first embodiment.

FIG. 12 is a cross-sectional view of the first TFT and the second TFT illustrating a state in which a third insulating film is etched in the ninth step included in the array substrate manufacturing step according to the first embodiment.

FIG. 13 is a cross-sectional view of the first TFT and the second TFT illustrating a state in which a fourth metal film is etched in a tenth step included in the array substrate manufacturing step according to the first embodiment.

FIG. 14 is a cross-sectional view of a first TFT and a second TFT provided in an array substrate according to a second embodiment.

FIG. 15 is a cross-sectional view of the first TFT and the second TFT illustrating a state in which a third photoresist film is developed in an eighth step included in the array substrate manufacturing step according to the second embodiment.

FIG. 16 is a cross-sectional view of the first TFT and the second TFT illustrating a state in which a third metal film is wet etched in the eighth step included in the array substrate manufacturing step according to the second embodiment.

FIG. 17 is a cross-sectional view of the first TFT and the second TFT illustrating a state in which a fourth insulating film is dry etched in the eighth step included in the array substrate manufacturing step according to the second embodiment.

FIG. 18 is a cross-sectional view of a first TFT and a second TFT provided in an array substrate according to a third embodiment.

FIG. 19 is a cross-sectional view of the first TFT and the second TFT illustrating a state in which a first photoresist film is developed through a first photomask in a sixth step included in an array substrate manufacturing step according to the third embodiment.

FIG. 20 is a cross-sectional view of the first TFT and the second TFT illustrating a state in which a fourth photoresist film is developed through a second photomask in a seventeenth step included in the array substrate manufacturing step according to the third embodiment.

FIG. 21 is a cross-sectional view of the first TFT and the second TFT illustrating a state in which the fourth photoresist film is developed in the seventeenth step included in the array substrate manufacturing step according to the third embodiment.

FIG. 22 is a cross-sectional view of the first TFT and the second TFT illustrating a state in which a second insulating film is dry etched in the seventeenth step included in the array substrate manufacturing step according to the third embodiment.

FIG. 23 is a cross-sectional view of a first TFT and a second TFT provided in an array substrate according to a fourth embodiment.

FIG. 24 is a cross-sectional view of the first TFT and the second TFT illustrating a state in which a second insulating film is dry etched in a sixth step included in an array substrate manufacturing step according to the fourth embodiment.

FIG. 25 is a cross-sectional view of a first TFT and a second TFT provided in an array substrate according to a fifth embodiment.

FIG. 26 is a cross-sectional view of the first TFT and the second TFT illustrating a state in which a second insulating film is dry etched in a sixth step included in an array substrate manufacturing step according to the fifth embodiment.

FIG. 27 is a cross-sectional view of a first TFT and a second TFT provided in an array substrate according to a sixth embodiment.

FIG. 28 is a cross-sectional view of a first TFT and a second TFT provided in an array substrate according to a seventh embodiment.

### DESCRIPTION OF EMBODIMENTS

### First Embodiment

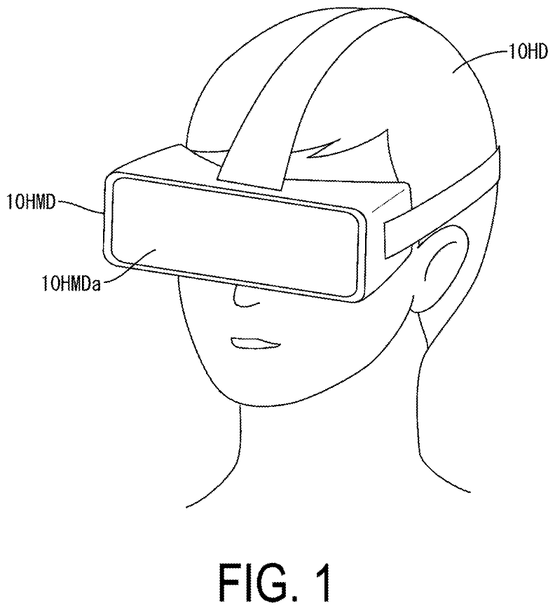

A first embodiment will be described with reference to FIG. 1 to FIG. 13. In the present embodiment, a goggle-type head-mounted display (Head-Mounted Display: HMD) 10HMD and a liquid crystal display device 10 used for the head-mounted display are exemplified. Note that some drawings show an X-axis, a Y-axis, and a Z-axis, and directions of these axes are drawn so as to be common in all the drawings.

The appearance of the goggle-type head-mounted display 10HMD will be described with reference to FIG. 1. As illustrated in FIG. 1, the head-mounted display 10HMD includes a head-mounted device 10HMDa mounted on the head 10HD of the user. The head-mounted device 10HMDa surrounds both eyes of the user.

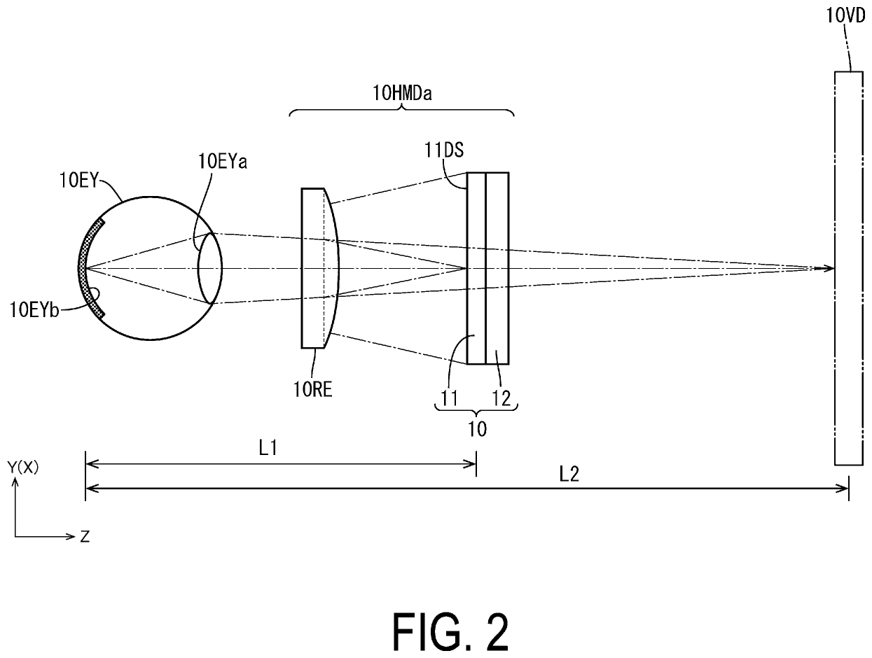

A configuration of the head-mounted device 10HMDa will be described with reference to FIG. 2. As illustrated in FIG. 2, the head-mounted device 10HMDa incorporates at least a liquid crystal display device 10 displaying an image and a lens unit 10RE focusing the image displayed on the liquid crystal display device 10 on an eyeball 10EY of the user. The liquid crystal display device 10 includes at least a liquid crystal panel (display device) 11 and a backlight device (illumination device) 12 irradiating the liquid crystal panel 11 with light. A main surface of the liquid crystal panel 11 on the lens unit 10RE side is a display surface 11DS displaying the image. The lens unit 10RE is disposed to be interposed between the liquid crystal display device 10 and the eyeball 10EY of the user. The lens unit 10RE imparts a refracting action to light. By adjusting the focal length of the lens unit 10RE, the user can recognize that an image focused on a retina 10EYb through a crystalline lens 10EYa of the eyeball 10EY is displayed on a virtual display 10VD that is apparently present at a position of a distance L2 from the eyeball 10EY. This distance L2 is much larger than an actual distance L1 from the eyeball 10EY to the liquid crystal display device 10. Accordingly, the user can visually recognize an enlarged image that is a virtual image displayed on the virtual display 10VD having a screen size (for example, from about several tens of inches to about several hundreds of inches) much larger than a screen size (for example, from about 0. several inches to about several inches) of the liquid crystal display device 10.

By mounting one liquid crystal display device 10 on the head-mounted device 10HMDa an image for a right eye and an image for a left eye can be displayed on the liquid crystal display device 10. Alternatively, by mounting two liquid crystal display devices 10 on the head-mounted device 10HMDa, the image for the right eye and the image for the left eye may be displayed on one of the liquid crystal display devices 10 and on the other of the liquid crystal display devices 10, respectively. The head-mounted device 10HMDa may be provided with earphones or the like that are addressed to the ears of the user and emit a sound.

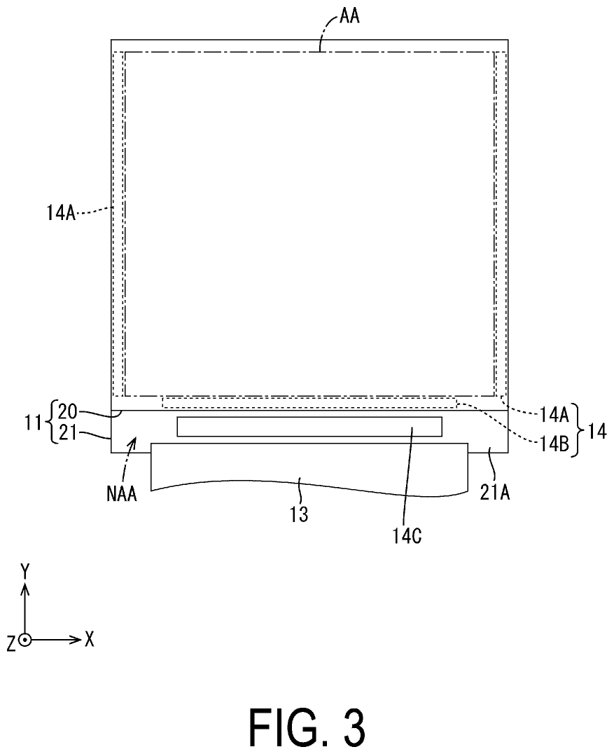

A configuration of the liquid crystal panel 11 included in the liquid crystal display device 10 will be described with reference to FIG. 3 and the like. Note that the configuration of the backlight device 12 is as known, and includes, for example, a light source such as an LED, an optical member that converts light from the light source into planar light by applying an optical effect to the light from the light source, and the like. As illustrated in FIG. 3, the liquid crystal panel 11 has a rectangular shape as a whole in a plan view. A center-side portion of the screen of the liquid crystal panel 11 is a display region AA in which an image is displayed. A frame-shaped outer peripheral portion surrounding the display region AA of the screen of the liquid crystal panel 11 is a non-display region NAA in which no image is displayed. A range surrounded by an alternating dotted-dashed line in FIG. 3 is the display region AA. The liquid crystal panel 11 according to the present embodiment is used in the head-mounted display 10HMD described above, and thus having an extremely high resolution, and the pixel density thereof is, for example, in the range from about 800 ppi to about 1800 ppi.

As illustrated in FIG. 3, the liquid crystal panel 11 is formed by bonding a pair of substrates 20 and 21 together. Of the pair of substrates 20 and 21, one disposed on a front side is a counter substrate (CF substrate) 20, and the other one disposed on a back side is an array substrate (active matrix substrate) 21. The counter substrate 20 and the array substrate 21 are each formed by layering various films on an inner face side of a respective one of glass substrates 20GS and 21GS that are substantially transparent and have excellent light-transmittance. The substrates 20GS and 21GS contain, for example, alkali-free glass as a main material. The array substrate 21 is larger than the counter substrate 20, and a part of the array substrate 21 protrudes laterally with respect to the counter substrate 20. A flexible substrate 13 is mounted on a protruding portion 21A of the array substrate 21. The flexible substrate 13 has a configuration in which a plurality of wiring line patterns are formed on a flexible base material having insulating properties. One end-side of the flexible substrate 13 is connected to the array substrate 21, and the other end-side thereof is connected to an external control substrate (signal supply source) (not illustrated). Various signals supplied from the control substrate are transmitted to the liquid crystal panel 11 via the flexible substrate 13.

As illustrated in FIG. 3, a circuit portion (peripheral circuit portion) 14 is provided in the non-display region NAA of the liquid crystal panel 11. The circuit portion 14 includes a first circuit portion 14A and a second circuit portion 14B. A pair of the first circuit portions 14A are disposed sandwiching the display region AA from both sides in the X-axis direction. The first circuit portion 14A is provided in a belt-shaped range extending along the Y-axis direction. The first circuit portion 14A is configured to supply a scanning signal to a gate wiring line 25 described later, and monolithically provided on the array substrate 21. The first circuit portion 14A is a Gate Driver Monolithic (GDM) circuit. The first circuit portion 14A includes a shift register circuit configured to output the scanning signal at a predetermined timing, a buffer circuit for amplifying the scanning signal, and the like. The second circuit portion 14B is disposed at a position interposed between the display region AA and the flexible substrate 13 in the Y-axis direction. The second circuit portion 14B is provided in a belt-shaped region extending along the X-axis direction. The second circuit portion 14B is configured to supply an image signal (data signal) to a source wiring line 26 described later, and monolithically provided on the array substrate 21. The second circuit portion 14B includes a demultiplexer circuit (source signal dividing circuit) and the like. The second circuit portion 14B has a switching function of dividing an image signal (source signal) supplied by a source driver 14C and distributing the divided image signal to each source wiring line 26. The first circuit portions 14A and the second circuit portion 14B constituting the circuit portion 14 are provided with various circuit elements including at least a first TFT (first switching element) 15. A detailed structure of the first TFT 15 will be described later.

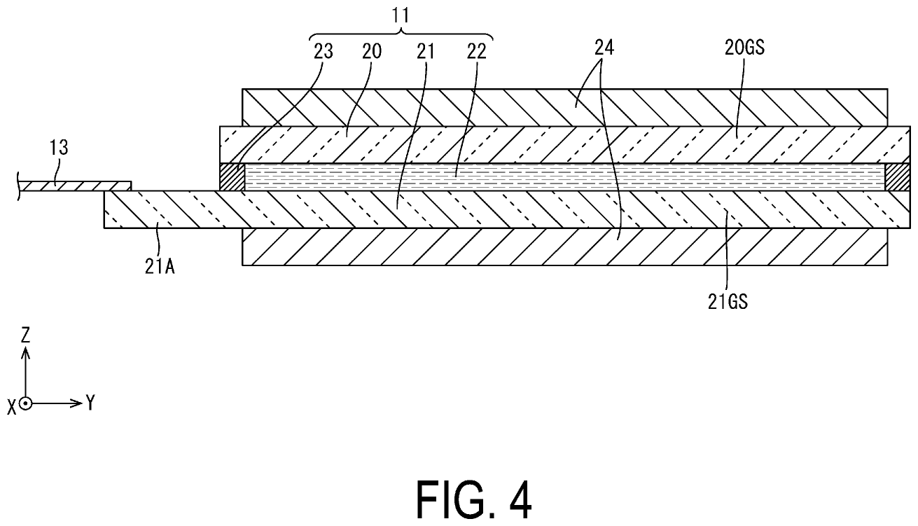

Next, a schematic cross-sectional configuration of the liquid crystal panel 11 will be described with reference to FIG. 4. As illustrated in FIG. 4, the pair of substrates 20 and 21 are disposed to face each other with a gap therebetween in the Z-axis direction that is the normal direction of plate surfaces of the substrates 20 and 21. At least a liquid crystal layer 22 and a sealing portion 23 sealing the liquid crystal layer 22 are each interposed between the pair of substrates 20 and 21. The liquid crystal layer 22 contains liquid crystal molecules that are a substance having optical characteristics changing according to an applied electrical field. The sealing portion 23 has a rectangular frame-like shape (endless ring shape) as a whole in a plan view, and surrounds over the entire periphery of the liquid crystal layer 22 in the non-display region NAA. A gap (cell gap) corresponding to the thickness of the liquid crystal layer 22 is maintained by the sealing portion 23. Note that polarizers 24 are bonded to outer face sides of the pair of substrates 20 and 21, respectively.

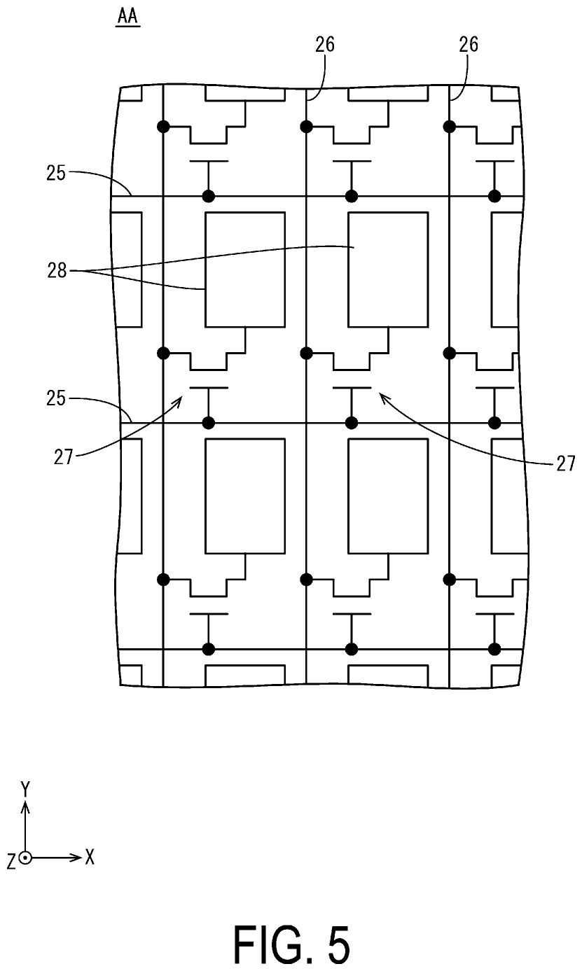

A plurality of gate wiring lines (first wiring lines or scanning wiring lines) 25 and a plurality of source wiring lines (second wiring lines or image wiring lines) 26 each forming a lattice pattern are disposed on the inner face side of the display region AA of the array substrate 21 as illustrated in FIG. 5. Each of the gate wiring lines 25 extends substantially in the X-axis direction to cross the display region AA. The plurality of gate wiring lines 25 are disposed side by side at intervals in the Y-axis direction. The scanning signal output from the first circuit portion 14A described above is sequentially supplied to each of the plurality of gate wiring lines 25 from an upper-stage side in FIG. 5. Each of the source wiring lines 26 extends substantially in the Y-axis direction to cross the display region AA, and intersects the plurality of gate wiring lines 25. The plurality of source wiring lines 26 are disposed at intervals in the X-axis direction. The image signals output from the second circuit portion 14B are distributed to the source wiring lines 26. A second TFT (second switching element) 27 and a pixel electrode 28 are each provided near an intersection of the gate wiring line 25 and the source wiring line 26. A plurality of the second TFTs 27 and a plurality of the pixel electrode 28 are regularly disposed in the X-axis direction and the Y-axis direction. The gate wiring line 25, the source wiring line 26, and the pixel electrode 28 are connected to the second TFT 27. When the second TFT 27 is driven based on the scanning signal supplied to the gate wiring line 25, the second TFT 27 charges the pixel electrode 28 to a potential based on the image signal supplied to the source wiring line 26.

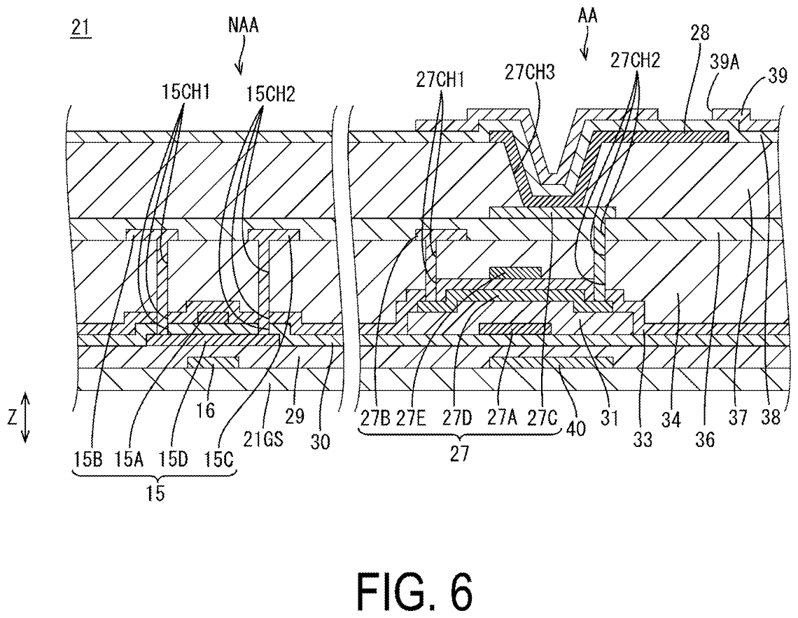

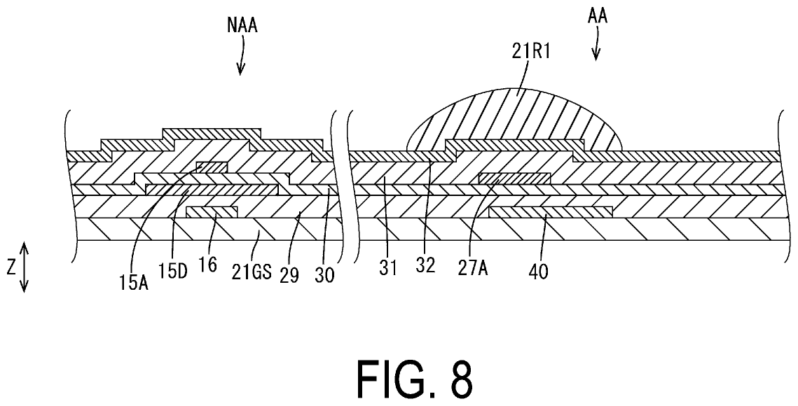

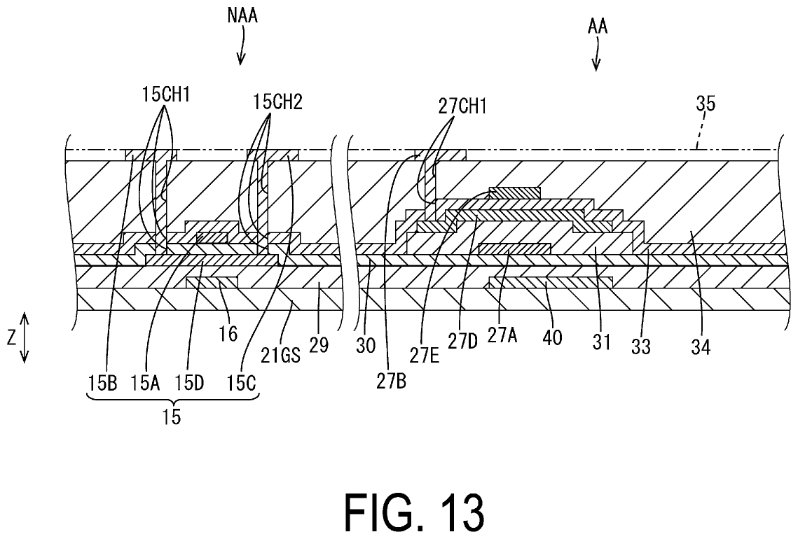

Subsequently, the various films layered on the glass substrate 21GS of the array substrate 21 will be described in detail with reference to FIG. 6. FIG. 6 illustrates a cross-sectional configuration of the circuit portion 14 (first TFT 15) in the non-display region NAA and a cross-sectional configuration of the display region AA (second TFT 27). As illustrated in FIG. 6, at least a first metal film (light blocking film), a base coat film 29, a first semiconductor film, a first insulating film 30, a second metal film (first conductive film), a second insulating film 31, a second semiconductor film 32 (see FIG. 8), a fourth insulating film 33, a third metal film (third conductive film), a third insulating film 34, a fourth metal film (second conductive film) 35 (see FIG. 13), a fifth insulating film 36, a fifth metal film, a sixth insulating film 37, a first transparent electrode film, a seventh insulating film 38, and a second transparent electrode film are layered on the glass substrate 21GS of the array substrate 21 in this order from the lower-layer side (glass substrate 21GS side).

The first metal film, the second metal film, the third metal film, the fourth metal film 35, and the fifth metal film are each a single layer film made of one kind of metal material or a layered film or alloy made of a different kinds of metal materials, and thus have conductivity and light-blocking properties. The first transparent electrode film and the second transparent electrode film are made of a transparent electrode material such as indium tin oxide (ITO), indium zinc oxide (IZO), or the like. The base coat film 29, the first insulating film 30, the second insulating film 31, the third insulating film 34, the fourth insulating film 33, the fifth insulating film 36, and the seventh insulating film 38 are all made of silicon oxide (SiO), silicon nitride (SiN), or the like that are a kind of an inorganic material (inorganic resin material). Among them, the first insulating film 30 and the fourth insulating film 33 are made of, for example, SiO, and film thicknesses thereof are in a range, for example, from about 80 nm to about 120 nm. A film thickness of the second insulating film 31 is larger than the film thickness of the first insulating film 30, and is, for example, about 300 nm. The third insulating film 34 is made of, for example, SiO, and a film thickness thereof is, for example, from 500 nm to 700 nm, and may be a single layer film of SiN or a layered film of SiN and SiO. The sixth insulating film 37 is made of PMMA (acrylic resin) that is a kind of an organic material (organic resin material). The sixth insulating film 37 made of the organic material usually has a larger film thickness than the base coat film 29, the first insulating film 30, the second insulating film 31, the fourth insulating film 33, the fifth insulating film 36, and the seventh insulating film 38 each made of the inorganic material.

The first semiconductor film is made of a polysilicon semiconductor material containing crystalline formed by a known method such as laser crystallization. The polysilicon semiconductor material of the first semiconductor film has a much higher electron mobility than an oxide semiconductor material. The second semiconductor film 32 is made of the oxide semiconductor material. The second semiconductor film 32 may contain, for example, at least one kind of metal element of In, Ga, and Zn, and for example, an In—Ga—Zn—O based semiconductor (for example, indium gallium zinc oxide) may be used. Here, the In—Ga—Zn—O based semiconductor is a ternary oxide of indium (In), gallium (Ga), and zinc (Zn), and a ratio (composition ratio) of In, Ga, and Zn is not particularly limited. For example, the ratio includes In:Ga:Zn=2:2:1, In:Ga:Zn=1:1:1, In:Ga:Zn=1:1:2, or the like. The In—Ga—Zn—O based semiconductor used for the second semiconductor film 32 may be an amorphous semiconductor or may be a crystalline semiconductor. The second semiconductor film 32 may contain another oxide semiconductor in place of the In—Ga—Zn—O based semiconductor. For example, the second semiconductor film 32 may contain an In—Sn—Zn—O based semiconductor (for example, In2O3-SnO2-ZnO; InSnZnO). The In—Sn—Zn—O based semiconductor is a ternary oxide of indium (In), tin (Sn), and zinc (Zn). Alternatively, the oxide semiconductor layer 4 may contain an In—W—Zn—O based semiconductor containing W (tungsten), an In—W—Sn—Zn—O based semiconductor, an In—Al—Zn—O based semiconductor, an In—Al—Sn—Zn—O based semiconductor, a Zn—O based semiconductor, an In—Zn—O based semiconductor, a Zn—Ti—O based semiconductor, a Cd—Ge—O based semiconductor, a Cd—Pb—O based semiconductor, CdO (cadmium oxide), a Mg—Zn—O based semiconductor, an In—Ga—Sn—O based semiconductor, an In—Ga—O based semiconductor, a Zr—In—Zn—O based semiconductor, a Hf—In—Zn—O based semiconductor, an Al—Ga—Zn—O based semiconductor, a Ga—Zn—O based semiconductor, an In—Ga—Zn—Sn—O based semiconductor, and the like. The oxide semiconductor material of the second semiconductor film 32 has characteristics of higher resistance value in a state in which no voltage is applied (off state) than the polysilicon semiconductor material. The oxide semiconductor material of the second semiconductor film 32 has higher electron mobility than an amorphous silicon semiconductor material.

Next, a cross-sectional configuration of the circuit portion 14 will be described in detail. As illustrated in FIG. 6, the circuit portion 14 includes the first TFT 15. The first TFT 15 includes a first gate electrode (first electrode) 15A, a first source electrode (third electrode) 15B, a first drain electrode (third electrode) 15C, and a first semiconductor portion 15D. The first semiconductor portion 15D is located on the lowermost layer side with respect to the electrodes 15A to 15C and is made of the first semiconductor film.

As illustrated in FIG. 6, the first gate electrode 15A is made of the second metal film. The first gate electrode 15A is disposed to overlap on an upper-layer side with respect to the first semiconductor portion 15D via the first insulating film 30. The first gate electrode 15A is disposed to overlap a center-side portion of the first semiconductor portion 15D.

As illustrated in FIG. 6, the first source electrode 15B and the first drain electrode 15C are made of the fourth metal film 35. A part of the first source electrode 15B and a part of the first drain electrode 15C are disposed to overlap on an upper-layer side with respect to the first semiconductor portion 15D via the first insulating film 30, the third insulating film 34, and the fourth insulating film 33. The first source electrode 15B is disposed to overlap one end-side portion of the first semiconductor portion 15D. The first drain electrode 15C is disposed to overlap the other end-side portion of the first semiconductor portion 15D. The first source electrode 15B and the first drain electrode 15C are disposed near the first gate electrode 15A. The first source electrode 15B and the first drain electrode 15C are connected to the first semiconductor portion 15D through two first contact holes 15CH1 and 15CH2, respectively, described later.

In the circuit portion 14, a first light blocking portion 16 is provided at a position overlapping at least the first gate electrode 15A. The first light blocking portion 16 is made of the first metal film located at the lowermost layer among the films included in the array substrate 21. The first light blocking portion 16 is disposed to overlap on a lower-layer side with respect to a channel region of the first semiconductor portion 15D, the channel region being generated according to application of a voltage to the first gate electrode 15A. Thus, the light emitted from the backlight device 12 to the channel region of the first semiconductor portion 15D from the lower-layer side can be blocked by the first light blocking portion 16. This can suppress a variation in the characteristics of the first TFT 15 which may occur when the channel region of the first semiconductor portion 15D is irradiated with light.

Next, a cross-sectional configuration of the display region AA will be described in detail. As illustrated in FIG. 6, the second TFT 27 is disposed in the display region AA. The second TFT 27 includes a second gate electrode (second electrode) 27A, a second source electrode (fourth electrode) 27B, a second drain electrode (sixth electrode) 27C, a second semiconductor portion 27D, and a third gate electrode (fifth electrode) 27E. The second semiconductor portion 27D located on the upper-layer side than the second gate electrode 27A and on the lower-layer side than the second source electrode 27B, the second drain electrode 27C, and the third gate electrode 27E, and is made of the second semiconductor film 32.

As illustrated in FIG. 6, the second gate electrode 27A is made of a part of the second metal film different from the first gate electrode 15A. The second gate electrode 27A is disposed to overlap on a lower-layer side with respect to the second semiconductor portion 27D via the second insulating film 31. The second gate electrode 27A is disposed to overlap a center-side portion of the second semiconductor portion 27D. As described above, both the first gate electrode 15A and the second gate electrode 27A are made of the second metal film, and thus the number of layers of the metal film can be reduced as compared with a case where the first gate electrode and the second gate electrode are made of different metal films (conductive films), respectively.

As illustrated in FIG. 6, the third gate electrode 27E is made of the third metal film. The third gate electrode 27E is disposed to overlap on the upper-layer side with respect to the second semiconductor portion 27D via the fourth insulating film 33. As described above, the second semiconductor portion 27D is interposed between the second gate electrode 27A and the third gate electrode 27E from below and above, respectively. That is, the second TFT 27 according to the present embodiment has a double gate structure. The third gate electrode 27E is disposed to overlap the center-side portion of the second semiconductor portion 27D. The third gate electrode 27E is smaller in size in plan view than the second gate electrode 27A, and is disposed to overlap a center-side portion of the second gate electrode 27A. The second gate electrode 27A and the third gate electrode 27E are connected to each other. At least one of the second gate electrode 27A and the third gate electrode 27E is connected to the gate wiring line 25 (see FIG. 5). Thus, the scanning signal supplied to the gate wiring line 25 is supplied to the second gate electrode 27A and the third gate electrode 27E to cause the second gate electrode 27A and the third gate electrode 27E to have the same potential. When the scanning signal is supplied to the second gate electrode 27A and third gate electrode 27E, a channel region is generated in each of a portion on the lower-layer side (second gate electrode 27A side) and a portion on the upper-layer side (third gate electrode 27E side) of the second semiconductor portion 27D due to an electrical field acting on the second semiconductor portion 27D from the second gate electrode 27A and third gate electrode 27E. Accordingly, the channel regions can be stably generated in the second semiconductor portion 27D.

As illustrated in FIG. 6, the second source electrode 27B is made of a part of the fourth metal film 35 different from the first source electrode 15B and the first drain electrode 15C. At least a part of the second source electrode 27B is disposed to overlap on an upper-layer side with respect to the second semiconductor portion 27D via the third insulating film 34 and the fourth insulating film 33. The second source electrode 27B is disposed to overlap one end-side portion of the second semiconductor portion 27D. The second source electrode 27B is disposed at a position near the second gate electrode 27A and the third gate electrode 27E. The second source electrode 27B is connected to the source wiring line 26 (see FIG. 5). The second source electrode 27B is connected to the second semiconductor portion 27D through a second contact hole 27CH1 described later. As described above, the first source electrode 15B, the first drain electrode 15C, and the second source electrode 27B are all made of the fourth metal film 35, and thus the number of layers of the metal film can be reduced as compared with a case where the first source electrode, the first drain electrode, and the second source electrode are made of different metal films, respectively.

As illustrated in FIG. 6, the second drain electrode 27C is made of the fifth metal film. At least a part of the second drain electrode 27C is disposed to overlap on the upper-layer side with respect to the second semiconductor portion 27D via the third insulating film 34, the fourth insulating film 33, and the fifth insulating film 36. The second drain electrode 27C is disposed to overlap the center-side portion and the other end-side portion of the second semiconductor portion 27D. The second drain electrode 27C is disposed to overlap the second gate electrode 27A and the third gate electrode 27E. A third contact hole 27CH2 is provided in the third insulating film 34, the fourth insulating film 33, and the fifth insulating film 36 each interposed between the second drain electrode 27C and the second semiconductor portion 27D. The third contact hole 27CH2 is disposed at a position overlapping the second drain electrode 27C and the second semiconductor portion 27D and not overlapping the third gate electrode 27E. Specifically, in the third contact hole 27CH2, the second drain electrode 27C disposed at a position overlapping an end-side portion of the second drain electrode 27C opposite to the second source electrode 27B side and the other end-side portion of the second semiconductor portion 27D is connected to the second semiconductor portion 27D through the third contact hole 27CH2.

As illustrated in FIG. 6, the pixel electrode 28 and a common electrode 39 are disposed in the display region AA. The pixel electrode 28 is made of the first transparent electrode film. A part of the pixel electrode 28 is disposed to overlap the second drain electrode 27C. A fourth contact hole 27CH3 is provided in the sixth insulating film 37 interposed between the pixel electrode 28 and the second drain electrode 27C. The fourth contact hole 27CH3 is disposed at a position overlapping the pixel electrode 28 and the second drain electrode 27C. The fourth contact hole 27CH3 is disposed at a position overlapping the second gate electrode 27A, the second semiconductor portion 27D, and the third gate electrode 27E. The pixel electrode 28 is connected to the second drain electrode 27C through the fourth contact hole 27CH3.

The common electrode 39 is made of the second transparent electrode film. The common electrode 39 is disposed over substantially the entire display region AA. Accordingly, the common electrode 39 is disposed to overlap on the upper-layer side with respect to all of the pixel electrodes 28 disposed in the display region AA via the seventh insulating film 38. A plurality of slits 39A are each formed to be opened in a respective one of portions of the common electrodes 39 each overlapping a respective one of the plurality of pixel electrodes 28. A common potential signal that is a common potential (reference potential) is supplied to the common electrode 39. When the pixel electrode 28 is charged to a potential based on the image signal transmitted to the source wiring line 26 according to driving of the second TFT 27, a potential difference is generated between the pixel electrode 28 and the common electrode 39. Then, a fringe electrical field (oblique electrical field) including a component in a normal direction with respect to the plate surface of the array substrate 21 in addition to a component along the plate surface of the array substrate 21 is generated between an opening edge of the slit 39A in the common electrode 39 and the pixel electrode 28. Accordingly, by using this fringe electrical field, it is possible to control the alignment state of the liquid crystal molecules included in the liquid crystal layer 22, and a predetermined display is formed on the basis of the alignment state of the liquid crystal molecules. In other words, the operation mode of the liquid crystal panel 11 according to the present embodiment is a fringe field switching (FFS) mode.

In the display region AA, a second light blocking portion 40 is provided at a position overlapping at least the entire third gate electrode 27E. The second light blocking portion 40 is disposed to overlap most of the second gate electrode 27A. The second light blocking portion 40 is made of a part of the first metal film different from the first light blocking portion 16. The second light blocking portion 40 is disposed to overlap on a lower-layer side with respect to each channel region of the second semiconductor portion 27D, each channel region being generated according to application of voltage to the second gate electrode 27A and the third gate electrode 27E. Thus, the light emitted from the backlight device 12 to each channel region of the second semiconductor portion 27D from the lower-layer side can be blocked by the second light blocking portion 40. This can suppress a variation in the characteristics of the second TFT 27 which may occur when each channel region of the second semiconductor portion 27D is irradiated with light.

As described above, in the present embodiment, the first semiconductor portion 15D constituting the first TFT 15 disposed in the circuit portion 14 is made of the first semiconductor film, and the first semiconductor film is made of the polysilicon semiconductor material having characteristics of higher mobility than the oxide semiconductor material. Accordingly, a plane size of the first TFT 15 (first semiconductor portion 15D) can be reduced, and thus a reduction of the non-display region NAA (frame narrowing) of the liquid crystal display device 10 and low power consumption due to downsizing of the first TFT 15 can be achieved. The second semiconductor portion 27D constituting the second TFT 27 disposed in the display region AA is made of the second semiconductor film 32, and the second semiconductor film 32 is made of the oxide semiconductor material having characteristic of a higher resistance value at an off-voltage application (off state) even when the second semiconductor film 32 is irradiated with light from the backlight device 12. Accordingly, the area of the second light blocking portion 40 disposed on the lower-layer side of the second semiconductor portion 27D can be reduced as compared with the case where the polysilicon semiconductor material is used, and thus an aperture ratio (backlight light transmittance) of the display region AA can be improve and the low power consumption of the liquid crystal display device 10 can be achieved. Accordingly, the size of the second TFT 27 can be reduced, and thus it is suitable for improving resolution of the liquid crystal panel 11, and it is particularly suitable for using the liquid crystal panel 11 for the head-mounted display 10HMD.

The first contact holes 15CH1 and 15CH2 and the second contact hole 27CH1 will be described. As illustrated in FIG. 6, the first contact holes 15CH1 and 15CH2 and the second contact hole 27CH1 are common in that they are opened in the third insulating film 34 and the insulating films (the first insulating film 30, the second insulating film 31, and the fourth insulating film 33) located on the lower-layer side of the third insulating film 34. Due to this common point, in manufacturing the array substrate 21, before performing film formation of the fourth metal film 35, the first contact holes 15CH1 and 15CH2 and the second contact hole 27CH1 can be provided in the third insulating film 34 and the like in the same step (a ninth step described later). At this time, dry etching is mainly used for etching. As compared with the case where the first contact hole and the second contact hole are formed in different steps as in the related art, the tact can be shortened according to the present embodiment.

As illustrated in FIG. 6, the second insulating film 31 included in the array substrate 21 according to the present embodiment is disposed to overlap at least the second semiconductor portion 27D and is not formed in a range overlapping the first semiconductor portion 15D. Specifically, in the display region AA, the second insulating film 31 is patterned to remain in a plurality of ranges each having an island shape overlapping at least a respective one of the second semiconductor portions 27D each included in a respective one of the plurality of second TFTs 27. The second insulating film 31 is patterned to be removed over substantially the entire non-display region NAA, and is not formed in a range overlapping each of the first semiconductor portions 15D included in a respective one of the plurality of first TFTs 15. In this way, the first contact holes 15CH1 and 15CH2 disposed to overlap the first semiconductor portion 15D in the non-display region NAA are not provided in the second insulating film 31 but are provided in the three layers of the first insulating film 30, the fourth insulating film 33, and the third insulating film 34. On the other hand, the second contact hole 27CH1 disposed to overlap the second semiconductor portion 27D in the display region AA is provided in two layers of the fourth insulating film 33 and the third insulating film 34.

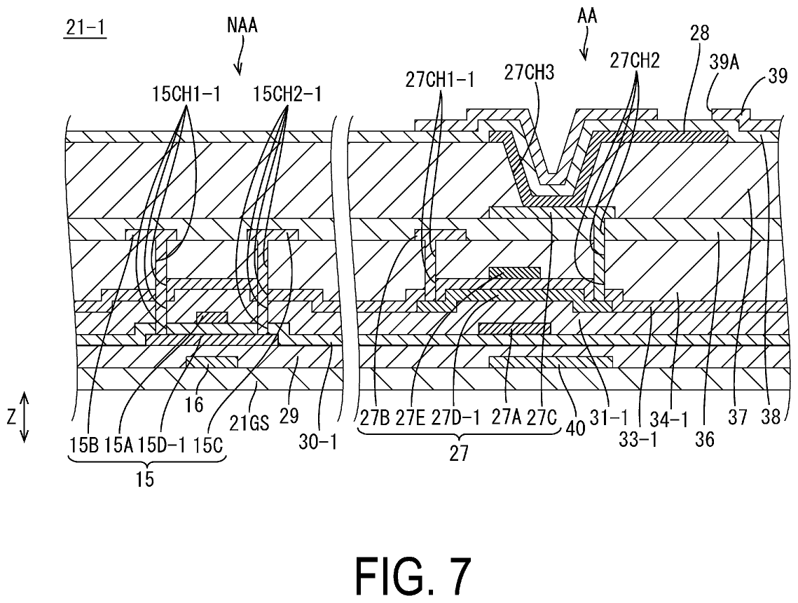

Here, an array substrate 21-1 of a comparative example in which a second insulating film 31-1 remains to be solid-like over the entire display region AA and the non-display region NAA will be described with reference to FIG. 7. The comparative example has the same configuration as that of the present embodiment illustrated in FIG. 6 except for a formation range of the second insulating film 31-1. In the comparative example illustrated in FIG. 7, the second insulating film 31-1 is disposed to be solid-like over the entire display region AA and the non-display region NAA, and is also present in a range overlapping a first semiconductor portion 15D-1 disposed in the non-display region NAA. Thus, first contact holes 15CH1-1 and 15CH2-1 disposed to overlap the first semiconductor portion 15D-1 in the non-display region NAA are provided in four layers of a first insulating film 30-1, the second insulating film 31-1, a fourth insulating film 33-1, and a third insulating film 34-1. On the other hand, a second contact hole 27CH1-1 disposed in the display region AA is provided in two layers of the fourth insulating film 33-1 and the third insulating film 34-1. As a result, in the comparative example, a difference between the number of layers of the insulating films 30-1, 31-1, 33-1, and 34-1 each provided with the first contact holes 15CH1-1 and 15CH2-1 and the number of layers of the insulating films 33-1 and 34-1 each provided with the second contact hole 27CH1-1 is “2”. Thus, in the comparative example, a difference between the total film thickness of the insulating films 30-1, 31-1, 33-1, and 34-1 each provided with the first contact holes 15CH1-1 and 15CH2-1 and the total film thickness of the insulating films 33-1 and 34-1 each provided with the second contact hole 27CH1-1 coincides with the total film thickness of the first insulating film 30-1 and the second insulating film 31-1, and is specifically in a range from about 380 nm to about 420 nm. In the comparative example having such a configuration, in providing the first contact holes 15CH1-1 and 15CH2-1 and the second contact hole 27CH1-1 in the same step, even after the second contact hole 27CH1-1 is formed in the insulating films 33-1 and 34-1, etching is continuously performed to form the first contact holes 15CH1-1 and 15CH2-1 in all of the insulating films 30-1, 31-1, 33-1, and 34-1. Thus, in the comparative example, a situation may occur in which a second semiconductor portion 27D-1 serving as a stop film is over etched through the second contact hole 27CH1-1.

On the other hand, as illustrated in FIG. 6, in the present embodiment, the second insulating film 31 is not formed in the range overlapping the first semiconductor portion 15D, and thus the number of layers of the insulating films 30, 33, and 34 each provided with the first contact holes 15CH1 and 15CH2 is “3”, and can be reduced than the number of layers (“2”) in the comparative example. Thus, a difference between the number of layers of the insulating films 30, 33, and 34 each provided with the first contact holes 15CH1 and 15CH2 and the number of layers of the insulating films 33 and 34 each provided with the second contact hole 27CH1 is “1”, which is smaller than the difference (“2”) according to the comparative example. A difference between the total film thickness of the insulating films 30, 33, and 34 each provided with the first contact holes 15CH1 and 15CH2 and the total film thickness of the insulating films 33 and 34 each provided with the second contact hole 27CH1 coincides with the thickness of the first insulating film 30, and is specifically in a range from about 80 nm to about 120 nm (about ¼ of the comparative example). In providing the first contact holes 15CH1 and 15CH2 and the second contact hole 27CH1 in the same step, even when the etching is continuously performed to form the first contact holes 15CH1 and 15CH2 in all of the insulating films 30, 33, and 34 after the second contact hole 27CH1 is formed in the insulating films 33 and 34, time for which the etching is continued can be made shorter than in the comparative example. Accordingly, in the present embodiment, a situation is less likely to occur in which the second semiconductor portion 27D serving as the stop film is over etched through the second contact hole 27CH1.

In the present embodiment, as described above, the second insulating film 31 selectively remains in the display region AA, and thus in manufacturing the array substrate 21, patterning of the second insulating film 31 is required. When a dedicated step for patterning the second insulating film is required, there is a problem in that the tact becomes longer accordingly. In this regard, in the present embodiment, as illustrated in FIG. 6, the second insulating film 31 in the display region AA is provided to selectively remain in a range overlapping the second semiconductor portion 27D. In this way, the second insulating film 31 can be patterned in the step of patterning the second semiconductor portion 27D in manufacturing the array substrate 21. Accordingly, a dedicated step for patterning the second insulating film 31 is not required, and the tact can be shortened.

As illustrated in FIG. 6, the fourth insulating film 33 according to the present embodiment is disposed to overlap at least the first semiconductor portion 15D and the second semiconductor portion 27D. Specifically, the fourth insulating film 33 is disposed to be solid-like over the entire display region AA and the non-display region NAA, and is disposed overlap both the first semiconductor portion 15D disposed in the non-display region NAA and the second semiconductor portion 27D disposed in the display region AA. Accordingly, a part of each of the first contact holes 15CH1 and 15CH2 and a part of the second contact hole 27CH1 are provided in the fourth insulating film 33. In this way, the first gate electrode 15A can be covered with a part of the fourth insulating film 33 overlapping the first semiconductor portion 15D. As compared with the case where the fourth insulating film is not formed in the range overlapping the first semiconductor portion 15D, the third insulating film 34 made of an organic material can be prevented from being directly layered on the first gate electrode 15A.

The present embodiment has the above-described structure, and a manufacturing method of the liquid crystal panel 11 will be subsequently described. The manufacturing method of the liquid crystal panel 11 includes a counter substrate manufacturing step (CF substrate manufacturing step) of manufacturing the counter substrate 20, an array substrate manufacturing step of manufacturing the array substrate 21, and a bonding step of bonding the manufactured counter substrate 20 and the array substrate 21 together. Hereinafter, the array substrate manufacturing step of the above steps will be described.

The array substrate manufacturing step includes a first step of performing film formation and patterning of the first metal film, a second step of performing film formation and patterning of the base coat film 29, a third step of performing film formation and anneal processing or the like and then patterning of the first semiconductor film, a fourth step of performing film formation of the first insulating film 30, a fifth step of performing film formation and patterning of the first metal film, a sixth step of performing film formation and patterning of the second insulating film 31 and the second semiconductor film 32, a seventh step of performing film formation of the fourth insulating film 33, an eighth step of performing film formation and patterning of the third metal film, a ninth step of performing film formation and patterning of the third insulating film 34, a tenth step of performing film formation and patterning of the fourth metal film 35, an eleventh step of performing film formation and patterning of the fifth insulating film 36, a twelfth step of performing film formation and patterning of the fifth metal film, a thirteenth step of performing film formation and patterning of the sixth insulating film 37, a fourteenth step of performing film formation and patterning of the first transparent electrode film, a fifteenth step of performing film formation of the seventh insulating film 38, and a sixteenth step of performing film formation and patterning of the second transparent electrode film. Among these steps, the sixth step, the ninth step, and the tenth step will be described in detail below with reference to FIG. 8 to FIG. 13. FIG. 8 to FIG. 13 illustrate the same cross-sectional configuration as that in FIG. 6.

The term “patterning” described above means process of a film based on a general photolithography method. Specifically, the process, that is, the patterning of a film to be processed is performed by performing the film formation of the photoresist film on the film to be processed, exposing the photoresist film with an exposure device through a photomask having a predetermined pattern, and then developing the photoresist film, and performing etching through the developed photoresist film.

After the first metal film is patterned to provide the first gate electrode 15A and the second gate electrode 27A through the fifth step, the sixth step is performed. In the sixth step, film formation of the second insulating film 31, the second semiconductor film 32, and a first photoresist film 21R1 each being solid-like are continuously performed on the upper-layer side of the first metal film. Thereafter, the first photoresist film 21R1 is exposed using the exposure device and a photomask having a predetermined pattern. When the exposed first photoresist film 21R1 is developed, the first photoresist film 21R1 is patterned as illustrated in FIG. 8. The patterned first photoresist film 21R1 remains in a range having an island shape near each of the second gate electrodes 27A in the display region AA.

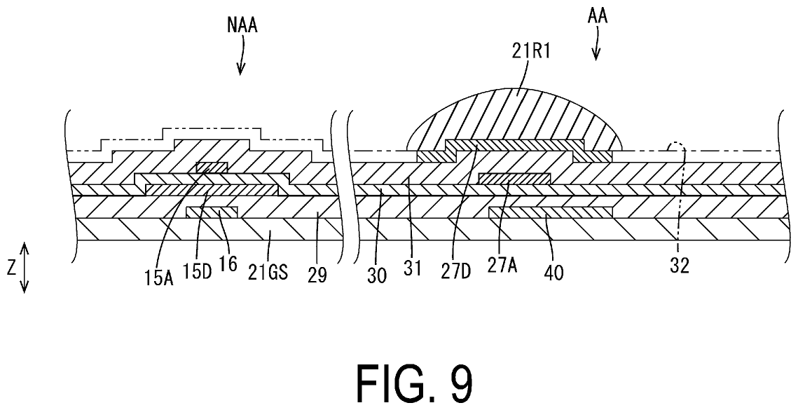

In the sixth step, the second semiconductor film 32 is wet etched through the developed first photoresist film 21R1 (first etching step). As a result, the exposed portion of the second semiconductor film 32 not covered with the first photoresist film 21R1 is selectively removed, and the portion thereof being covered with the first photoresist film 21R1 and thus not exposed selectively remains. In the present embodiment, the second semiconductor film 32 is wet etched, and thus the entire portion covered with the first photoresist film 21R1 does not remain, and the portion covered with an outer edge portion of the first photoresist film 21R1 is removed. That is, a formation range of the wet etched second semiconductor film 32 is one size smaller than a formation range of the first photoresist film 21R1. As a result, as illustrated in FIG. 9, the second semiconductor portion 27D is formed by a remaining portion of the second semiconductor film 32.

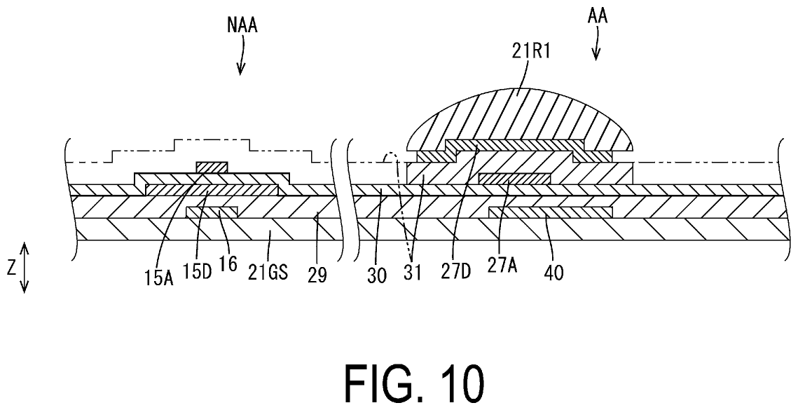

Subsequently, in the sixth step, the second insulating film 31 is dry etched through the first photoresist film 21R1 (second etching step). As a result, the exposed portion of the second insulating film 31 not covered with the first photoresist film 21R1 is selectively removed, and the portion thereof being covered with the first photoresist film 21R1 and thus not exposed selectively remains. In the present embodiment, the second insulating film 31 is dry etched, and thus substantially entire portion covered with the first photoresist film 21R1 (portion overlapping the first photoresist film 21R1) remains. That is, a formation range of the dry etched second insulating film 31 substantially coincides with the formation range of the first photoresist film 21R1, and is one size larger than the formation range of the second semiconductor film 32. As illustrated in FIG. 10, an outer edge of the second insulating film 31 patterned in this manner is not aligned with an outer edge of the second semiconductor portion 27D and protrudes outward. As described above, the outer edge of the second insulating film 31 and the outer edge of the second semiconductor portion 27D form a step shape. Thereafter, the first photoresist film 21R1 undergoes ashing and is removed.

As described above, in the sixth step, by patterning the second insulating film 31 using the first photoresist film 21R1 as the mask, the second insulating film 31 can be provided in the range overlapping the second semiconductor portion 27D. A dedicated photoresist film or the like for patterning the second insulating film 31 is not required, and thus steps related to film formation, exposure, and development thereof are reduced. Thus, the tact can be further shortened. Moreover, using the first photoresist film 21R1 as the mask, the second semiconductor film 32 is wet etched and then the second insulating film 31 is dry etched, and thus the second semiconductor portion 27D that is one size smaller than the formation range of the first photoresist film 21R1 and the second insulating film 31 that is substantially the same as the formation range of the first photoresist film 21R1 can be formed. Accordingly, the outer edge of the second semiconductor portion 27D and the outer edge of the second insulating film 31 are not aligned with each other to form the step shape, and thus when film formation of the fourth insulating film 33 is performed on the upper-layer side of the second insulating film 31 in the subsequent seventh step, the coverage of the fourth insulating film 33 is improved.

When the second insulating film 31 is dry etched in the sixth step, an etching rate of the second insulating film 31 as the target film is preferably set higher than an etching rate of the first insulating film 30 as the stop film of the second insulating film 31. That is, a selection ratio of the second insulating film 31 when the second insulating film 31 is dry etched is preferably set larger than 1. In this way, when the second insulating film 31 is dry etched, a situation is less likely to occur in which the exposed portion of the first insulating film 30 not covered with the first photoresist film 21R1 is over etched.

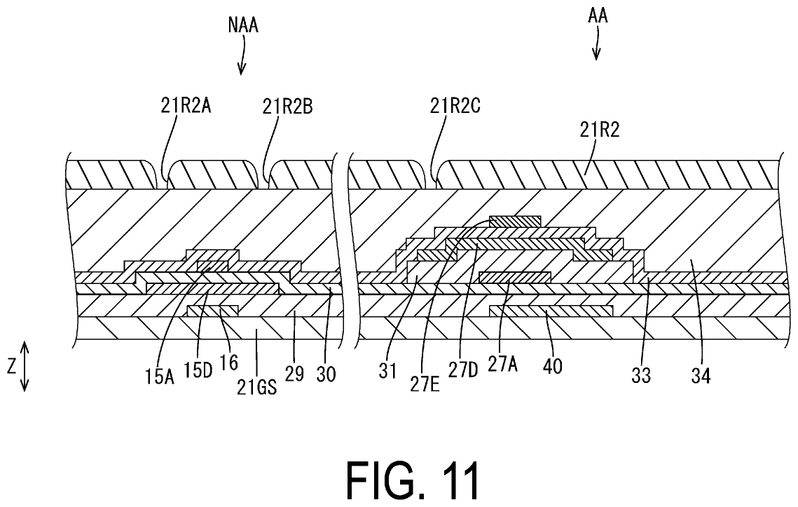

The seventh step is performed after the sixth step, and film formation of the fourth insulating film 33 to be solid-like is performed on the upper-layer side of the second semiconductor film 32. Subsequently, when the eighth step is performed, the third gate electrode 27E is provided by performing the film formation of the third metal film on the upper-layer side of the fourth insulating film 33 and then patterning the third metal film. Thereafter, the ninth step is performed. In the ninth step, film formation of the third insulating film 34 and the second photoresist film 21R2 each to be solid-like are continuously performed on the upper-layer side of the third metal film. Thereafter, the second photoresist film 21R2 is exposed using the exposure device and a photomask having a predetermined pattern. When the exposed second photoresist film 21R2 is developed, the second photoresist film 21R2 is patterned as illustrated in FIG. 11. The patterned second photoresist film 21R2 remains over the display region AA and the non-display region NAA, and includes a plurality of openings 21R2A to 21R2C. Specifically, the second photoresist film 21R2 includes two first openings 21R2A and 21R2B each opened in a range overlapping a respective one of both end-side portions of each first semiconductor portion 15D, and one second opening 21R2C opened in a range overlapping one end-side portion of each second semiconductor portion 27D.

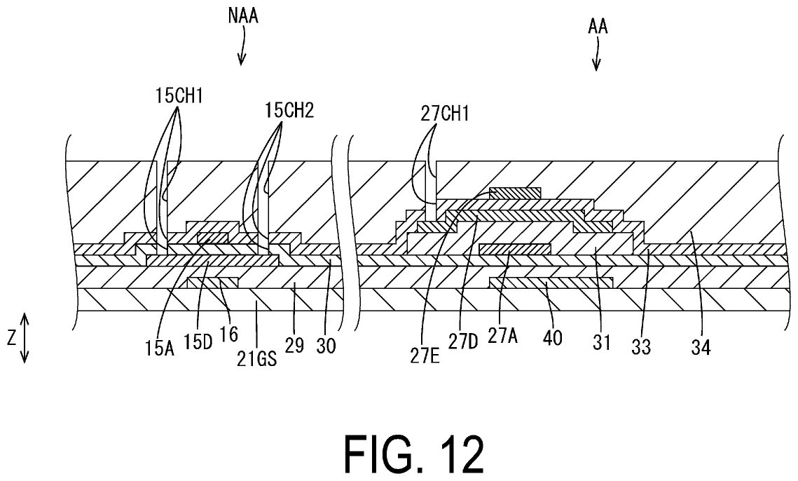

In the ninth step, the third insulating film 34 is etched through the developed second photoresist film 21R2. As the etching at this time, dry etching is mainly used in order to realize high resolution. This etching is continuously performed on the third insulating film 34 and the insulating films 30 and 33 located on the lower-layer side than the third insulating film 34 through the openings 21R2A to 21R2C of the second photoresist film 21R2. The etching performed through the first openings 21R2A and 21R2B is continuously performed on the three layers of the third insulating film 34, the fourth insulating film 33, and the first insulating film 30 in this order from the upper-layer side using the first semiconductor film as the stop film. The etching performed through the second opening 21R2C is continuously performed on the two layers of the third insulating film 34 and the fourth insulating film 33 in this order from the upper-layer side using the second semiconductor film 32 as the stop film. When the etching is performed in this manner, as illustrated in FIG. 12, the first contact holes 15CH1 and 15CH2 each opened over the three layers of the third insulating film 34, the fourth insulating film 33, and the first insulating film 30 are provided at positions overlapping the first openings 21R2A and 21R2B, respectively, of the second photoresist film 21R2. The second contact hole 27CH1 opened over the two layers of the third insulating film 34 and the fourth insulating film 33 is provided at a position overlapping the second opening 21R2C of the second photoresist film 21R2.

As described above, in the ninth step, by patterning the third insulating film 34, the first contact holes 15CH1 and 15CH2 and the second contact hole 27CH1 can be provided together. Compared with a case where the first contact holes 15CH1 and 15CH2 and the second contact hole 27CH1 are provided in different steps, the number of times of patterning the insulating films can be reduced. Moreover, the patterning of the first insulating film 30 and the fourth insulating film 33 is performed continuously with the patterning of the third insulating film 34. Thus, the first contact holes 15CH1 and 15CH2 and the second contact hole 27CH1 are substantially provided in one step (ninth step). Thus, the tact can be shortened. In addition, the first contact holes 15CH1 and 15CH2 are not provided in the second insulating film 31 but are provided in the three layers of the first insulating film 30, the fourth insulating film 33, and the third insulating film 34. Thus, according to the present embodiment, the number of layers of the insulating film 30, 33, and 34 each provided with the first contact holes 15CH1 and 15CH2 can be reduced by one as compared with the comparative example illustrated in FIG. 7. That is, a difference between the number of layers of the insulating films 30, 33, and 34 each provided with the first contact holes 15CH1 and 15CH2 and the number of layers of the insulating films 33 and 34 each provided with the second contact hole 27CH1 is smaller than the comparative example. In providing the first contact holes 15CH1 and 15CH2 and the second contact hole 27CH1 in the same ninth step, even when the etching is continuously performed to form the first contact holes 15CH1 and 15CH2 in all of the insulating films 30, 33, and 34 after the second contact hole 27CH1 is formed in the insulating films 33 and 34, time for which the etching is continued can be made shorter than in the comparative example. Accordingly, the situation is less likely to occur in which the second semiconductor portion 27D serving as the stop film is over etched through the second contact hole 27CH1.

After the first contact holes 15CH1 and 15CH2 and the second contact hole 27CH1 are provided through the ninth step, the tenth step is performed. In the tenth step, film formation of the fourth metal film is performed on the upper-layer side of the third insulating film 34 and then the fourth metal film is patterned. Accordingly, as illustrated in FIG. 13, the first source electrode 15B, the first drain electrode 15C, and the second source electrode 27B are provided. The first source electrode 15B is connected to one end-side portion of the first semiconductor portion 15D through the first contact hole 15CH1. The first drain electrode 15C is connected to the other end-side portion of the first semiconductor portion 15D through the first contact hole 15CH2. The second source electrode 27B is connected to one end-side portion of the second semiconductor portion 27D through the second contact hole 27CH1. As described above, in the tenth step, by patterning the fourth metal film 35, the first source electrode 15B, the first drain electrode 15C, and the second source electrode 27B can be provided together. Compared to a case where the first source electrode, the first drain electrode, and the second source electrode are provided by patterning different metal films, the number of times of performing film formation and patterning of the metal films can be reduced.

As described above, the liquid crystal panel (display device) 11 of the present embodiment includes the first semiconductor portion 15D made of the first semiconductor film, the first insulating film 30 disposed on the upper-layer side of the first semiconductor film, the first gate electrode (first electrode) 15A made of the second metal film (first conductive film) disposed on the upper-layer side of the first insulating film 30 and disposed to overlap a part of the first semiconductor portion 15D, the second gate electrode (second electrode) 27A made of a part of the second metal film different from the first gate electrode 15A, the second insulating film 31 disposed on the upper-layer side of the second metal film, the second semiconductor portion 27D made of the second semiconductor film 32 disposed on the upper-layer side of the second insulating film 31 including a part of the second semiconductor portion 27D being disposed to overlap the second gate electrode, 27A, the third insulating film 34 disposed on the upper-layer side than the second semiconductor film 32, the first source electrode 15B and the first drain electrode 15C (third electrodes) made of the fourth metal film (second conductive film) 35 disposed on the upper-layer side of the third insulating film 34 and disposed at the position overlapping the first semiconductor portion 15D and not overlapping the first gate electrode 15A, and the second source electrode (fourth electrode) 27B made of a part of the fourth metal film 35 different from the first source electrode 15B and the first drain electrode 15C and disposed to overlap a part of the second semiconductor portion 27D. The second insulating film 31 is disposed to overlap at least the second semiconductor portion 27D and is not formed in the range overlapping the first semiconductor portion 15D, the first contact holes 15CH1 and 15CH2 connecting the first source electrode 15B and the first drain electrode 15C, respectively, to the first semiconductor portion 15D are provided in the first insulating film 30 and the third insulating film 34 at the positions overlapping the first semiconductor portion 15D, the first source electrode 15B, and the first drain electrode 15C and the second contact hole 27CH1 connecting the second source electrode 27B to the second semiconductor portion 27 is provided in the third insulating film 34 at the position overlapping the second semiconductor portion 27D and the second source electrode 27B.

The first insulating film 30 is interposed between the first gate electrode 15A and the first semiconductor portion 15D, and thus the channel region can be generated in the first semiconductor portion 15D due to a voltage applied to the first gate electrode 15A. The second insulating film 31 is interposed between the second gate electrode 27A and the second semiconductor portion 27D, and thus the channel region can be generated in the second semiconductor portion 27D due to a voltage applied to the second gate electrode 27A.

Both the first gate electrode 15A and the second gate electrode 27A are made of the second metal film, and thus the number of layers of the conductive film can be reduced as compared with a case where the first gate electrode and the second gate electrode are made of different conductive films, respectively. The first source electrode 15B, the first drain electrode 15C, and the second source electrode 27B are all made of the fourth metal film 35, and thus the number of layers of the conductive film can be reduced as compared with the case where the first source electrode, the first drain electrode, and the second source electrode are made of different conductive films, respectively. In addition, before performing film formation of the fourth metal film 35, the first contact holes 15CH1 and 15CH2 and the second contact hole 27CH1 can be provided in the third insulating film 34 and the like in the same step. Thus, the tact can be shortened.

The second insulating film 31 is disposed to overlap at least the second semiconductor portion 27D and is not formed in the range overlapping the first semiconductor portion 15D, and thus the first contact holes 15CH1 and 15CH2 are not provided in the second insulating film 31 but are provided in at least the two layers of the first insulating film 30 and the third insulating film 34. When the second insulating film is also present in a range overlapping the first semiconductor portion 15D, the first contact holes are each provided over at least the three layers of the first insulating film 30, the second insulating film 31, and the third insulating film 34. As described above, the second insulating film 31 is not formed in the range overlapping the first semiconductor portion 15D, and thus the number of layers of the insulating films 30, 33, and 34 each provided with the first contact holes 15CH1 and 15CH2 can be reduced. Thus, the difference between the number of layers of the insulating films 30, 33, and 34 each provided with the first contact holes 15CH1 and 15CH2 and the number of layers of the insulating films 33 and 34 each provided with the second contact hole 27CH1 becomes smaller. Accordingly, when the first contact holes 15CH1 and 15CH2 and the second contact hole 27CH1 are provided in the same step, a situation is less likely to occur in which the second semiconductor portion 27D is over etched through the second contact hole 27CH1.

In addition, the fourth insulating film 33 disposed on the upper-layer side of the second semiconductor film 32 and on the lower-layer side than the third insulating film 34, and the third gate electrode (fifth electrode) 27E made of the third metal film (third conductive film) disposed on the upper-layer side of the fourth insulating film 33 and on the lower-layer side of the third insulating film 34 and disposed to overlap a part of the second semiconductor portion 27D are included, and the third gate electrode 27E is connected to the second gate electrode 27A. The fourth insulating film 33 is interposed between the third gate electrode 27E and the second semiconductor portion 27D, and thus the channel region can be generated in the second semiconductor portion 27D due to a voltage applied to the third gate electrode 27E. The electrical field acts on the second semiconductor portion 27D from both the second gate electrode 27A and the third gate electrode 27E to which the voltage is applied, and thus the channel region can be stably generated in the second semiconductor portion 27D.

The fourth insulating film 33 is disposed to overlap at least the first semiconductor portion 15D and the second semiconductor portion 27D, and a part of each of the first contact holes 15CH1 and 15CH2 and a part of the second contact hole 27CH1 are provided in the fourth insulating film 33. The first gate electrode 15A can be covered with a part of the fourth insulating film 33 overlapping the first semiconductor portion 15D. The first contact holes 15CH1 and 15CH2 are provided in the three layers of the first insulating film 30, the third insulating film 34, and the fourth insulating film 33. The second contact hole 27CH1 is provided in the two layers of the third insulating film 34 and the fourth insulating film 33.

The pixel electrode 28, the display region AA in which the pixel electrode 28 is disposed and the image is displayed, the second drain electrode (sixth electrode) 27C disposed in the display region AA and connected to the pixel electrode 28, the gate wiring line (first wiring line) 25 disposed in the display region AA, the source wiring line (second wiring line) 26 disposed in the display region AA, and the circuit portion 14 supplying the signal to at least one of the gate wiring line 25 and the source wiring line 26. The first semiconductor film is made of the polysilicon semiconductor material, the second semiconductor film 32 is made of the oxide semiconductor material, the first semiconductor portion 15D, the first gate electrode 15A, the first source electrode 15B, and the first drain electrode 15C are disposed in the circuit portion 14, the second semiconductor portion 27D, the second gate electrode 27A, and the second source electrode 27B are disposed in the display region AA, the second gate electrode 27A is connected to the gate wiring line 25, the second source electrode 27B is connected to the source wiring line 26, and the second drain electrode 27C is connected to the second semiconductor portion 27D. The signal from the circuit portion 14 is supplied to at least one of the gate wiring line 25 and the source wiring line 26. When a signal from the gate wiring line 25 is supplied to the second gate electrode 27A, a channel region is generated in the second semiconductor portion 27D, and thus a signal from the source wiring line 26 is supplied from the second source electrode 27B to the third gate electrode 27E, and the pixel electrode 28 is charged to a potential based on the signal from the source wiring line 26. The polysilicon semiconductor material of the first semiconductor film has characteristics of higher mobility than the oxide semiconductor material. Accordingly, a plane size of the first TFT 15 (first semiconductor portion 15D) can be reduced, and thus a reduction of the non-display region NAA (frame narrowing) of the display device and low power consumption due to downsizing of the first TFT 15 can be achieved. A switching speed of the first semiconductor portion 15D disposed in the circuit portion 14 can be increased, and thus a display defect such as flickers and afterimages is less likely to occur in the image displayed by the pixel electrodes 28 in the display region AA. The second semiconductor film 32 is made of the oxide semiconductor material having characteristic of a higher resistance value at the off-voltage application (off state) even when the second semiconductor film 32 is irradiated with light from the backlight device 12. Accordingly, the area of the second light blocking portion 40 disposed on the lower-layer side of the second semiconductor portion 27D can be reduced as compared with the case where the polysilicon semiconductor material is used, and thus the aperture ratio (backlight light transmittance) of the display region AA can be improve and the low power consumption of the liquid crystal display device 10 can be achieved.

The manufacturing method of the liquid crystal panel 11 of the present embodiment includes performing film formation of the first semiconductor film and patterning the first semiconductor film to provide the first semiconductor portion 15D, performing film formation of the first insulating film 30 on the upper-layer side of the first semiconductor film, performing film formation of the second metal film on the upper-layer side of the first insulating film 30 and patterning the second metal film to provide a first gate electrode 15A and the second gate electrode 27A disposed to overlap a part of the first semiconductor portion 15D, performing film formation of the second insulating film 31 on the upper-layer side of the second metal film, performing film formation of the second semiconductor film 32 on the upper-layer side of the second insulating film 31 and patterning the second semiconductor film 32 to provide the second semiconductor portion 27D including a part disposed to overlap the second gate electrode 27A, patterning the second insulating film 31 to overlap at least the second semiconductor portion 27D and not being formed in the range overlapping the first semiconductor portion 15D, performing film formation of the third insulating film 34 on the upper-layer side than the second semiconductor film 32 and patterning the third insulating film 34 to provide each part of the first contact holes 15CH1 and 15CH2 at the position overlapping a part of the first semiconductor portion 15D and not overlapping the first gate electrode 15A and to provide the second contact hole 27CH1 at the position overlapping a part of the second semiconductor portion 27D, patterning the first insulating film 30 subsequent to the third insulating film 34 to provide a part of the first contact holes 15CH1 and 15CH2 at the position overlapping a part of the first semiconductor portion 15D and not overlapping the first gate electrode 15A and performing film formation of the fourth metal film 35 on the upper-layer side of the third insulating film 34 and patterning the fourth metal film 35 to provide the first source electrode 15B and the first drain electrode 15C each disposed to overlap a respective one of the first contact holes 15CH1 and 15CH2 and connected to the first semiconductor portion 15D through the first contact holes 15CH1 and 15CH2, respectively, and the second source electrode 27B disposed to overlap the second contact hole 27CH1 and connected to the second semiconductor portion 27D through the second contact hole 27CH1.

By patterning the second metal film, the first gate electrode 15A and the second gate electrode 27A can be provided together. Compared to a case where the first gate electrode and the second gate electrode are provided by patterning different conductive films, the number of times of performing the film formation and patterning of the conductive films can be reduced. By patterning the fourth metal film 35, the first source electrode 15B, the first drain electrode 15C, and the second source electrode 27B can be provided together. Compared to a case where the first source electrode, the first drain electrode, and the second source electrode are provided by patterning different conductive films, the number of times of performing the film formation and patterning of the conductive films can be reduced. In addition, by patterning the third insulating film 34, the first contact holes 15CH1 and 15CH2 and the second contact hole 27CH1 can be provided together. Compared with a case where the first contact holes and the second contact hole are provided in different steps, the number of times of patterning the insulating films can be reduced. In addition, the patterning of the first insulating film 30 is performed continuously with the patterning of the third insulating film 34. Thus, the first contact holes 15CH1 and 15CH2 and the second contact hole 27CH1 are substantially provided in one step. Thus, the tact can be shortened.

The first contact holes 15CH1 and 15CH2 provided by patterning the first insulating film 30 and the third insulating film 34 are not provided in the second insulating film 31 but are each provided in at least the two layers of the first insulating film 30 and the third insulating film 34. When the second insulating film is also present in a range overlapping the first semiconductor portion 15D, the first contact holes are each provided over at least the three layers of the first insulating film 30, the second insulating film 31, and the third insulating film 34. As described above, the second insulating film 31 is not formed in the range overlapping the first semiconductor portion 15D, and thus the number of layers of the insulating films 30, 33, and 34 each provided with the first contact holes 15CH1 and 15CH2 can be reduced. Thus, the difference between the number of layers of the insulating films 30, 33, and 34 each provided with the first contact holes 15CH1 and 15CH2 and the number of layers of the insulating films 33 and 34 each provided with the second contact hole 27CH1 becomes smaller. Accordingly, when the first contact holes 15CH1 and 15CH2 and the second contact hole 27CH1 are provided in the same step, a situation is less likely to occur in which the second semiconductor portion 27D is over etched through the second contact hole 27CH1.

In patterning the second semiconductor film 32, film formation of the first photoresist film 21R1 is performed on the upper-layer side of the second semiconductor film 32, the first photoresist film 21R1 is exposed and developed, and then the second semiconductor film 32 is etched using the first photoresist film 21R1 as the mask to provide the second semiconductor portion 27D, and in patterning the second insulating film 31, the second insulating film 31 is etched using the first photoresist film 21R1 as the mask. As described above, by patterning the second insulating film 31 using the first photoresist film 21R1 as the mask, the second insulating film 31 can be provided in the range overlapping the second semiconductor portion 27D. A dedicated photoresist film for patterning the second insulating film 31 is not required, and thus steps related to film formation, exposure, and development thereof are reduced. Thus, the tact can be further shortened.

In patterning the second semiconductor film 32, the second semiconductor film 32 is wet etched, and in patterning the second insulating film 31, the second insulating film 31 is dry etched. The formation range of the second semiconductor portion 27D patterned by wet etching the second semiconductor film 32 is one size smaller than the formation range of the first photoresist film 21R1. On the other hand, when the second insulating film 31 is patterned by dry etching, the formation range of the second insulating film 31 becomes substantially the same as the formation range of the first photoresist film 21R1. Thus, the formation range of the second insulating film 31 is one size larger than the formation range of the second semiconductor portion 27D. Accordingly, the outer edge of the second semiconductor portion 27D and the outer edge of the second insulating film 31 are not aligned with each other to form the step shape, and thus when film formation of the fourth insulating film 33 is performed on the upper-layer side of the second insulating film 31, the coverage of the fourth insulating film 33 is improved.

In patterning the second insulating film 31, an etching rate of the second insulating film 31 is set higher than an etching rate of the first insulating film 30. When the second insulating film 31 is dry etched, a situation can be less likely to occur in which the first insulating film 30 is over etched.

### Second Embodiment

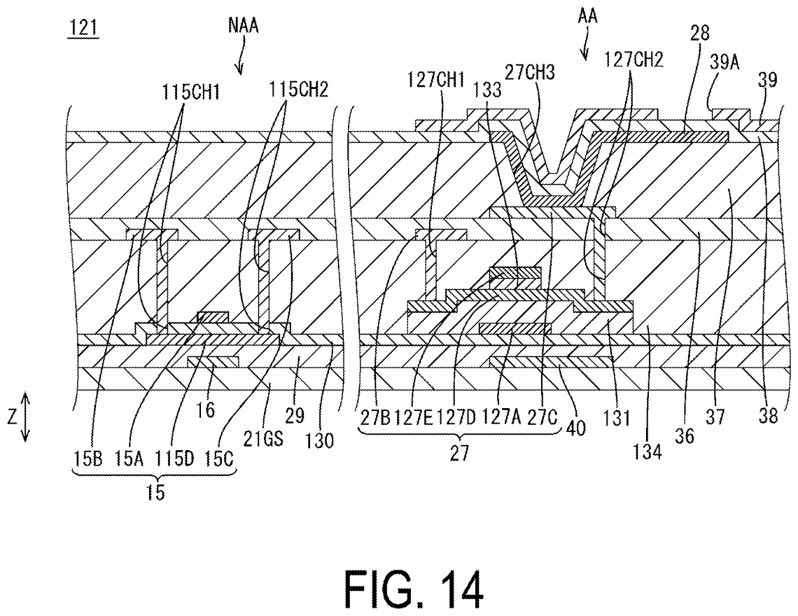

A second embodiment will be described with reference to FIG. 14 to FIG. 17. In the second embodiment, a case is described in which a configuration is changed to a fourth insulating film 133. Further, repetitive descriptions of structures, actions, and effects similar to those of the first embodiment described above will be omitted.

As illustrated in FIG. 14, the fourth insulating film 133 according to the present embodiment is disposed to overlap the entire third gate electrode 127E and to overlap a part of a second semiconductor portion 127D. Specifically, the fourth insulating film 133 has an island shape one size larger than the third gate electrode 127E, and is disposed to overlap the entire third gate electrodes 127E. The fourth insulating film 133 is disposed to overlap a center-side portion of the second semiconductor portion 127D and is in a non-overlapping relationship with both end-side portions thereof. The fourth insulating film 133 is one size larger than a second gate electrode 127A, and is also disposed to overlap the entire second gate electrode 127A. All of first contact holes 115CH1 and 115CH2, a second contact hole 127CH1, and a third contact hole 127CH2 are not formed in the fourth insulating film 133 having such a formation range.

In the present embodiment, a formation range of the second insulating film 131 substantially coincides with a formation range of the second semiconductor portion 127D, and an outer edge of the second insulating film 131 and an outer edge of the second semiconductor portion 127D are disposed to be substantially aligned with each other. In the present embodiment, the fourth insulating film 133 layered on an upper-layer side of the second semiconductor portion 127D is provided only in a formation range narrower than the second semiconductor portion 127D, and thus even when the outer edge of the second insulating film 131 and the outer edge of the second semiconductor portion 127D are disposed to be substantially aligned with each other, an adverse effect on a coverage of the fourth insulating film 133 is avoided.

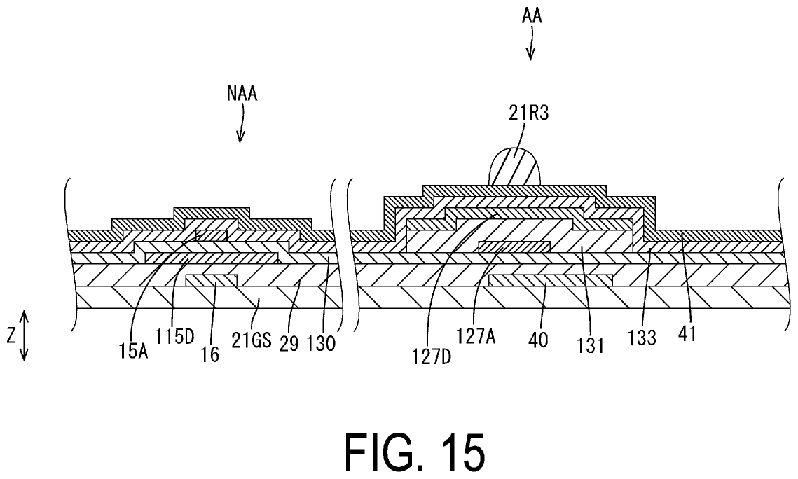

In order to provide the fourth insulating film 133 in the above-described formation range, in manufacturing an array substrate 121, patterning of the fourth insulating film 133 is required. In the present embodiment, patterning of the fourth insulating film 133 is performed in the eighth step in which the third metal film is patterned. The eighth step will be described in detail bellow with reference to FIG. 15 to FIG. 17.

When the eighth step is performed after film formation of the fourth insulating film 133 is performed through the seventh step, film formation of a third metal film (third conductive film) 41 and a third photoresist film (second photoresist film) 21R3 to be solid-like are continuously performed on an upper-layer side of the fourth insulating film 133. Thereafter, the third photoresist film 21R3 is exposed using the exposure device and a photomask having a predetermined pattern. When the exposed third photoresist film 21R3 is developed, the third photoresist film 21R3 is patterned as illustrated in FIG. 15. The patterned third photoresist film 21R3 remains in a range having an island shape near each of the second gate electrodes 127A in the display region AA. The third photoresist film 21R3 does not remain in the non-display region NAA.

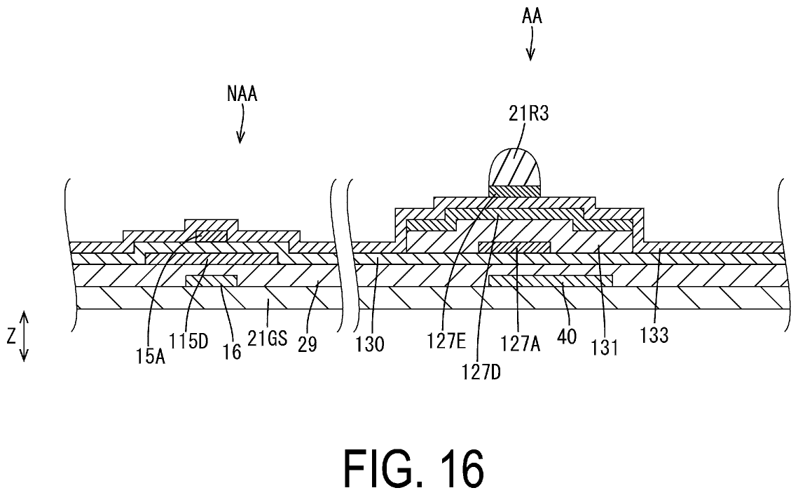

In the eighth step, the third metal film 41 is dry etched through the developed third photoresist film 21R3 (third etching step). Then, the exposed portion of the third metal film 41 not covered with the third photoresist film 21R3 is selectively removed, and the portion thereof being covered with the third photoresist film 21R3 and thus not exposed selectively remains. As a result, the third gate electrode 127E is formed by a remaining portion of the third metal film 41 as illustrated in FIG. 16.

Subsequently, in the eighth step, the fourth insulating film 133 is dry etched through the third photoresist film 21R3 (fourth etching step). Then, the exposed portion of the fourth insulating film 133 not covered with the third photoresist film 21R3 is selectively removed, and the portion thereof being covered with the third photoresist film 21R3 and thus not exposed selectively remains. In the present embodiment, the fourth insulating film 133 is dry etched, and thus substantially entire portion covered with the third photoresist film 21R3 (portion overlapping the third photoresist film 21R3) remains. That is, the formation range of the dry etched fourth insulating film 133 substantially coincides with a formation range of the third photoresist film 21R3. Thereafter, the third photoresist film 21R3 undergoes ashing and is removed.

As described above, in the eighth step, by patterning the fourth insulating film 133 using the third photoresist film 21R3 as the mask, the fourth insulating film 133 can be provided in the range overlapping the third gate electrode 127E. A dedicated photoresist film or the like for patterning the fourth insulating film 133 is not required, and thus steps related to film formation, exposure, and development thereof are reduced. Thus, the tact can be further shortened. Moreover, using the third photoresist film 21R3 as the mask, the third metal film 41 is wet etched and then the fourth insulating film 133 is dry etched, and thus the third gate electrode 127E that is one size smaller than the formation range of the third photoresist film 21R3 and the fourth insulating film 133 that is substantially the same as the formation range of the third photoresist film 21R3 can be formed. In the sixth step, the second semiconductor film 32 and the second insulating film 131 can be patterned together by dry etching, and thus switching to wet etching is not necessary, and the tact can be further shortened.

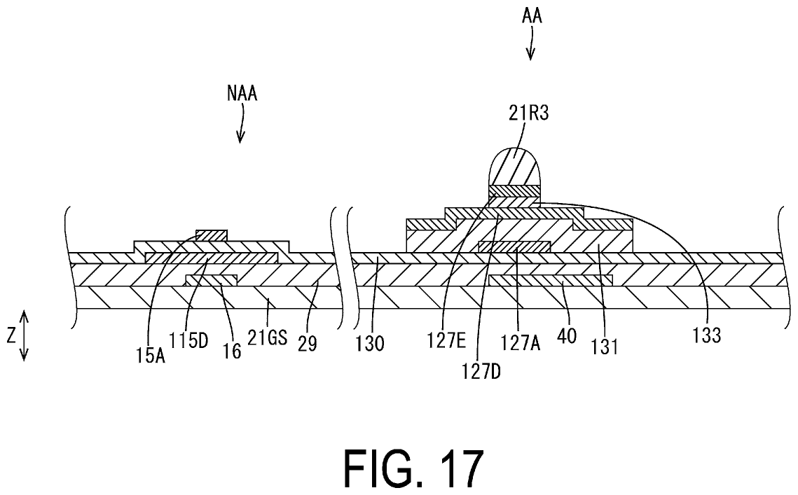

As described above, the formation range of the fourth insulating film 133 patterned through the eighth step is limited to at least the formation range of the second semiconductor portion 127D as illustrated in FIG. 17. That is, the fourth insulating film 133 is not present on the upper-layer side of the second insulating film 131 outside the formation range of the second semiconductor portion 127D (in a range not overlapping the second semiconductor portion 127D). Thus, even when a residue of the second insulating film 131 is present outside the second semiconductor portion 127D formation range, when the fourth insulating film 133 is dry etched in the eighth step, the residue of the second insulating film 131 can be removed.

The fourth insulating film 133 patterned through the eighth step is disposed to overlap the third gate electrode 127E and the center-side portion of the second semiconductor portion 127D, but is disposed not to overlap the entire first semiconductor portions 115D and both end-side portions of the second semiconductor portion 127D. Thus, when the third insulating film 134 is patterned in the subsequent ninth step, as illustrated in FIG. 14, the first contact holes 115CH1 and 115CH2 are each provided in two layers of the first insulating film 130 and the third insulating film 134, and the second contact hole 127CH1 is provided in one layer of the third insulating film 134. That is, the contact holes 115CH1, 115CH2, and 127CH1 are not provided in the fourth insulating film 133. In the present embodiment, a difference between the total film thickness of the insulating films 130 and 134 each provided with the first contact holes 115CH1 and 115CH2 and the film thickness of the insulating film 134 provided with the second contact hole 127CH1 coincides with the thickness of the first insulating film 130 as in the first embodiment described above, and specifically, it is only a range from about 80 nm to about 120 nm (about ¼ of the comparative example).

As described above, according to the present embodiment, the fourth insulating film 133 is disposed to overlap the third gate electrode 127E and the second semiconductor portion 127D. In this way, the fourth insulating film 133 is not formed at least in the range not overlapping the second semiconductor portion 127D. Thus, even when a residue of the second insulating film 131 is present at least in the range not overlapping the second semiconductor portion 127D, when the fourth insulating film 133 is patterned, the residue of the second insulating film 131 can be removed.

The fourth insulating film 133 is disposed to overlap the third gate electrode 127E. In the manufacturing, the third metal film (third conductive film) 41 constituting the third gate electrode 127E and the fourth insulating film 133 can be continuously patterned. The first contact holes 115CH1 and 115CH2 are each provided in the two layers of the first insulating film 130 and the third insulating film 134. The second contact hole 127CH1 is provided in one layer of the third insulating film 134.

In the manufacturing method of the liquid crystal panel 11 before performing film formation of the third insulating film 134, film formation of the fourth insulating film 133 is performed on the upper-layer side of the second semiconductor film 32, film formation of the third metal film 41 is performed on the upper-layer side of the fourth insulating film 133, and the third metal film 41 is patterned to provide the third gate electrode 127E disposed to overlap a part of the second semiconductor portion 127D, in patterning the third metal film 41, film formation of the third photoresist film (second photoresist film) 21R3 is performed on the upper-layer side of the third metal film 41, the third photoresist film 21R3 is exposed and developed, and then the third metal film 41 is etched using the third photoresist film 21R3 as the mask to provide the third gate electrode 127E, and in patterning the fourth insulating film 133, the fourth insulating film 133 is etched using the third photoresist film 21R3 as the mask. As described above, by patterning the fourth insulating film 133 using the third photoresist film 21R3 as the mask, the fourth insulating film 133 can be provided in the range overlapping the third gate electrode 127E. A dedicated photoresist film for patterning the fourth insulating film 133 is not required, and thus steps related to film formation, exposure, and development thereof are reduced. Thus, the tact can be further shortened. Moreover, even when the residue of the second insulating film 131 is present at least in the range not overlapping the second semiconductor portion 127D, when the fourth insulating film 133 is patterned, the residue of the second insulating film 131 can be removed.

### Third Embodiment

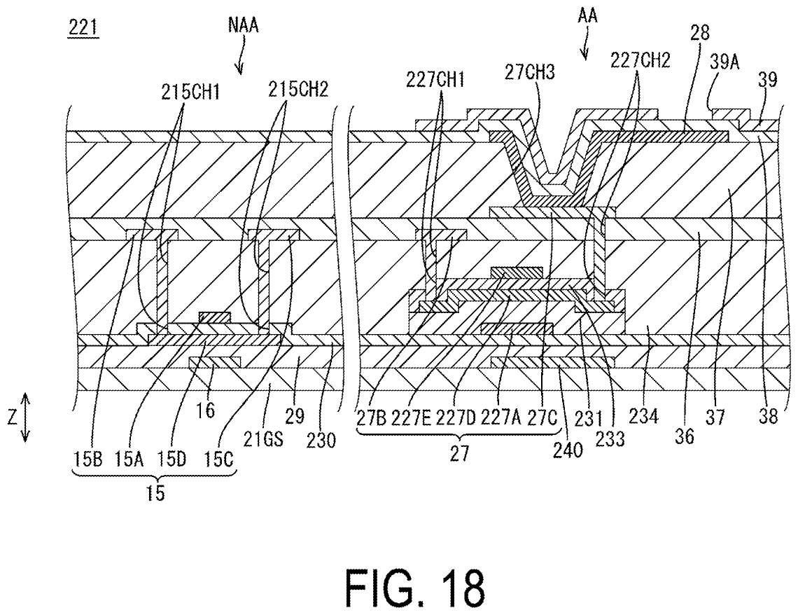

A third embodiment will be described with reference to FIG. 18 to FIG. 22. In the third embodiment, a case is described in which the first embodiment described above is changed to a configuration of a fourth insulating film 233. Further, repetitive descriptions of structures, actions, and effects similar to those of the first embodiment described above will be omitted.

As illustrated in FIG. 18, the fourth insulating film 233 according to the present embodiment is disposed to overlap the entire second semiconductor portion 227D. Specifically, the fourth insulating film 233 is provided to cover both end-side portions of the second semiconductor portion 227D in addition to the center-side portion thereof. A formation range of the fourth insulating film 233 is slightly wider than a formation range of the second semiconductor portion 227D. The formation range of the fourth insulating film 233 substantially coincides with the formation range of the second insulating film 231 located on the lower-layer side than the second semiconductor film 232, and an outer edge of the fourth insulating film 233 and an outer edge of the second insulating film 231 are disposed to be substantially aligned with each other.

In the fourth insulating film 233 having such a formation range, both the first contact holes 215CH1 and 215CH2 are not formed, but a part of each of the second contact hole 227CH1 and the third contact hole 227CH2 is provided. In the present embodiment, the first contact holes 215CH1 and 215CH2 are each provided in two layers of the first insulating film 230 and the third insulating film 234, whereas the second contact hole 227CH1 is provided in two layers of the third insulating film 234 and the fourth insulating film 233. As described above, a difference between the number of layers of the insulating films 230 and 234 each provided with the first contact holes 215CH1 and 215CH2 and the number of layers of the insulating films 233 and 234 each provided with the second contact hole 227CH1 is 0. In the present embodiment, a difference between the total film thickness of the insulating films 230 and 234 each provided with the first contact holes 215CH1 and 215CH2 and the total film thickness of the insulating films 233 and 234 each provided with the second contact hole 227CH1 coincides with a difference between the film thickness of the first insulating film 230 and the film thickness of the fourth insulating film 233, and is specifically in a range from about 0 nm to about 40 nm (about 1/10 of the comparative example). Accordingly, when the first contact holes 215CH1 and 215CH2 and the second contact hole 227CH1 are provided in the same step (ninth step), a situation is much less likely to occur in which the second semiconductor portion 227D serving as the stop film is over etched through the second contact hole 227CH1.

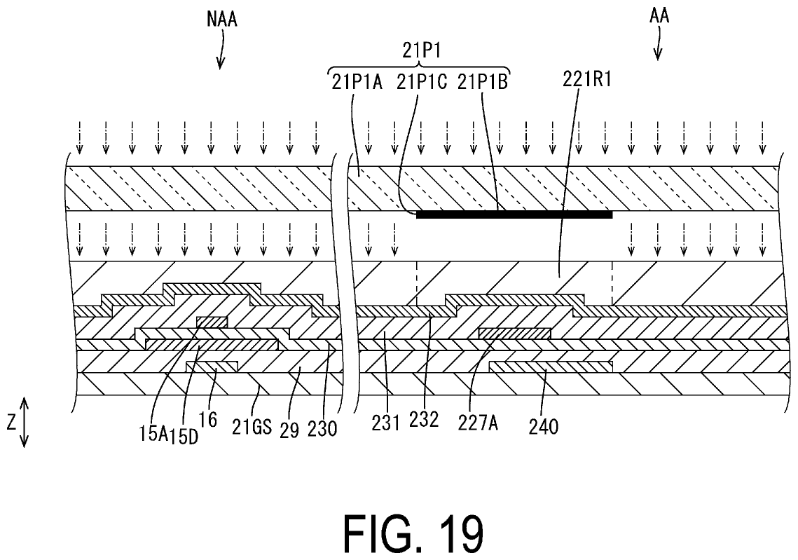

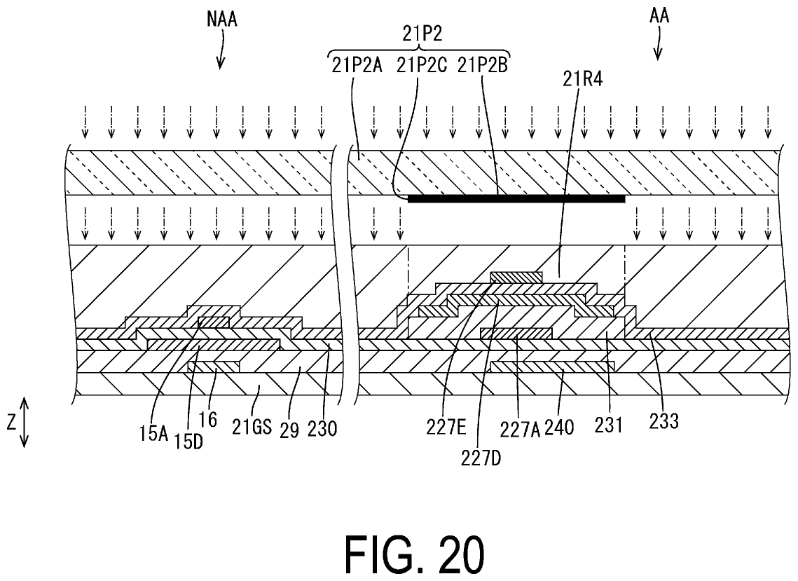

In order to provide the fourth insulating film 233 in the above-described formation range, in manufacturing an array substrate 221, patterning of the fourth insulating film 233 is required. In the present embodiment, the patterning of the fourth insulating film 233 is performed in the seventeenth step after the eighth step of patterning the third metal film. The seventeenth step is performed after the eighth step and before the ninth step. A second photomask 21P2 used in the seventeenth step is closely related to a first photomask 21P1 used in the sixth step of patterning the second semiconductor film 232, and thus the sixth step will be described first with reference to FIG. 19, and then the seventeenth step will be described with reference to FIG. 20 to FIG. 22.

In the sixth step, as illustrated in FIG. 19, film formation of the second insulating film 231, the second semiconductor film 232, and a first photoresist film 221R1 to be solid-like are continuously performed on the upper-layer side of the first metal film. Thereafter, the first photoresist film 221R1 is exposed using the exposure device and the first photomask 21P1. The first photoresist film 221R1 used in the sixth step is made of a positive-working photosensitive resist material. Here, the first photomask 21P1 will be described. The first photomask 21P1 includes a transparent first base material 21P1A having sufficiently high light-transmittance and a first light blocking film 21P1B formed on a main surface of the first base material 21P1A. The first light blocking film 21P1B blocks exposure light from the light source of the exposure device, and includes a partial first opening 21P1C. The first photomask 21P1 includes a light blocking region in which light is blocked in the formation range of the first light blocking film 21P1B, and a light transmitting region through which light is transmitted in the formation range of the first opening 21P1C (the non-formation range of the first light blocking film 21P1B). Each of the first light blocking films 21P1B is provided in a respective one of ranges each having an island shape including a range overlapping a second gate electrode 227A and a second light blocking portion 240 in the display region AA.

In the sixth step, when exposure light emitted from the light source of the exposure device is radiated to the first photoresist film 221R1 through the first photomask 21P1 having the configuration as described above, the first photoresist film 221R1 includes a range overlapping the first light blocking film 21P1B and not exposed and a range overlapping the first opening 21P1C and selectively exposed. When development is performed following the exposure, the exposed portion of the positive-working first photoresist film 221R1 is removed as the rate at which the photoresist film is dissolved by the developer, that is, the rate of dissolution, is fast. On the other hand, non-exposed portions may remain due to a low dissolution rate. With the above step, the first photoresist film 221R1 is patterned using the first photomask 21P1 (see FIG. 8). Thereafter, as in the first embodiment, the second insulating film 231 and the second semiconductor film 232 are etched through the first photoresist film 221R1.

In the eighth step, the third metal film is patterned to provide the third gate electrode 227E. Thereafter, the seventeenth step is performed. In the seventeenth step, film formation of a fourth photoresist film (third photoresist film) 21R4 to be solid-like is performed on the upper-layer side of the third metal film. Thereafter, the fourth photoresist film 21R4 is exposed using the exposure device and the second photomask 21P2. The fourth photoresist film 21R4 used in the seventeenth step is made of a positive-working photosensitive resist material. Here, the second photomask 21P2 will be described. The second photomask 21P2 includes a transparent second base material 21P2A having sufficiently high light-transmittance and a second light blocking film 21P2B formed on a main surface of the second base material 21P2A. The second light blocking film 21P2B blocks exposure light from the light source of the exposure device, and includes a partial second opening 21P2C. The second photomask 21P2 includes a light blocking region in which light is blocked in the formation range of the second light blocking film 21P2B, and a light transmitting region through which light is transmitted in the formation range of the second opening 21P2C (the non-formation range of the second light blocking film 21P2B). Each of the second light blocking films 21P2B is provided in a respective one of ranges each having an island shape including a range overlapping a second gate electrode 227A and a second light blocking portion 240 in the display region AA. The second light blocking film 21P2B is not present in the non-display region NAA. As described above, the second photomask 21P2 used in the seventeenth step has the same light blocking pattern (light-transmitting pattern) as that of the first photomask 21P1 used in the sixth step. Accordingly, a photomask having a dedicated light blocking pattern for patterning the fourth insulating film 233 in the seventeenth step is not required.

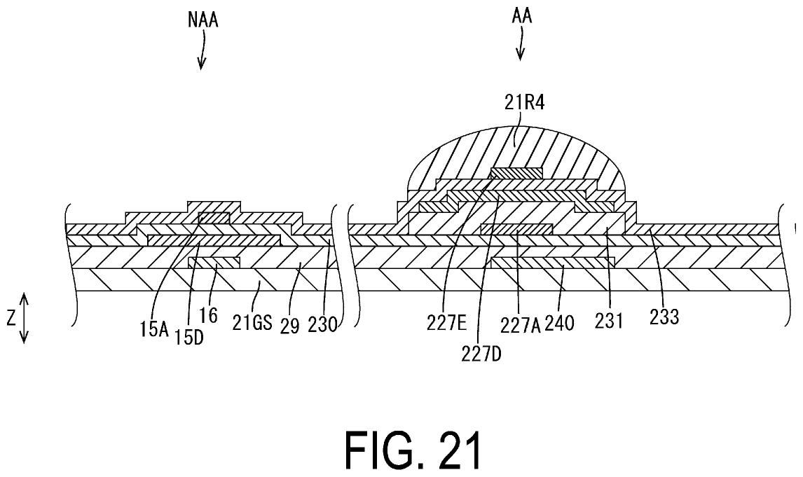

In the seventeenth step, when exposure light emitted from the light source of the exposure device is radiated to the fourth photoresist film 21R4 through the second photomask 21P2 having the configuration as described above, the fourth photoresist film 21R4 includes a range overlapping the second light blocking film 21P2B and not exposed and a range overlapping the second opening 21P2C and selectively exposed. When development is performed following the exposure, the exposed portion of the positive-working fourth photoresist film 21R4 is removed as the rate at which the photoresist film is dissolved by the developer, that is, the rate of dissolution, is fast. On the other hand, non-exposed portions may remain due to a low dissolution rate. With the above step, the fourth photoresist film 21R4 is patterned using the second photomask 21P2. The patterned fourth photoresist film 21R4 remains in a range having an island shape near each of the second gate electrodes 227A in the display region AA as illustrated in FIG. 21. The fourth photoresist film 21R4 does not remain in the non-display region NAA.

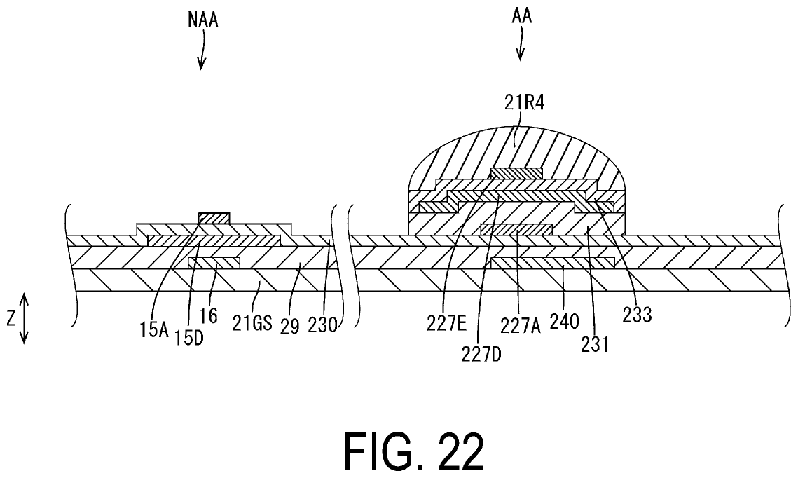

In the seventeenth step, the fourth insulating film 233 is dry etched through the fourth photoresist film 21R4. Then, the exposed portion of the fourth insulating film 233 not covered with the fourth photoresist film 21R4 is selectively removed, and the portion thereof being covered with the fourth photoresist film 21R4 and thus not exposed selectively remains. In the present embodiment, the fourth insulating film 233 is dry etched, and thus substantially entire portion covered with the fourth photoresist film 21R4 (portion overlapping the fourth photoresist film 21R4) remains. That is, the formation range of the dry etched fourth insulating film 233 substantially coincides with a formation range of the fourth photoresist film 21R4. Accordingly, the formation range of the fourth insulating film 233 substantially coincides with the formation range of the second insulating film 231, and is one size larger than the formation range of the second semiconductor film 232. As illustrated in FIG. 22, the outer edge of the fourth insulating film 233 patterned in this manner coincides with the outer edge of the second insulating film 231, and is not aligned with the outer edge of the second semiconductor portion 227D and protrudes outward. Thereafter, the fourth photoresist film 21R4 undergoes ashing and is removed.

As described above, in the seventeenth step, the light blocking pattern of the second photomask 21P2 used for the exposure of the fourth photoresist film 21R4 is the same as the light blocking pattern of the first photomask 21P1 used for the exposure of the first photoresist film 221R1, and thus the fourth insulating film 233 can be provided in a range overlapping the second semiconductor portion 227D. The fourth insulating film 233 provided in this manner is disposed to overlap the second semiconductor portion 227D, and thus a part of the second contact hole 227CH1 is provided in the fourth insulating film 233 at a position overlapping the second semiconductor portion 227D through the ninth step performed after the seventeenth step (see FIG. 18). Thus, the first contact holes 215CH1 and 215CH2 are each provided in the two layers of the first insulating film 230 and the third insulating film 234, and the second contact hole 227CH1 is provided in the two layers of the fourth insulating film 233 and the third insulating film 234. As described above, the difference between the number of layers of the insulating films 230 and 234 each provided with the first contact holes 215CH1 and 215CH2 and the number of layers of the insulating films 233 and 234 each provided with the second contact hole 227CH1 can be eliminated. Accordingly, when the first contact holes 215CH1 and 215CH2 and the second contact hole 227CH1 are provided in the ninth step, a situation is much less likely to occur in which the second semiconductor portion 227D is over etched through the second contact hole 227CH1. Moreover, even when a residue of the second insulating film 231 is present at least in the range not overlapping the second semiconductor portion 227D, when the fourth insulating film 233 is dry etched in the seventeenth step, the residue of the second insulating film 231 can be removed.

As described above, according to the present embodiment, the fourth insulating film 233 is disposed to overlap the second semiconductor portion 227D, and a part of the second contact hole 227CH1 is provided in the fourth insulating film 233 at the position overlapping the second semiconductor portion 227D. The first contact holes 215CH1 and 215CH2 are each provided in the two layers of the first insulating film 230 and the third insulating film 234. The second contact hole 227CH1 is provided in the two layers of the third insulating film 234 and the fourth insulating film 233. As described above, the difference between the number of layers of the insulating films 230 and 234 each provided with the first contact holes 215CH1 and 215CH2 and the number of layers of the insulating films 233 and 234 each provided with the second contact hole 227CH1 can be eliminated. Accordingly, when the first contact holes 215CH1 and 215CH2 and the second contact hole 227CH1 are provided in the same step, a situation is much less likely to occur in which the second semiconductor portion 227D is over etched through the second contact hole 227CH1.

In the manufacturing method of the liquid crystal panel 11 before performing film formation of the third insulating film 234, film formation of the fourth insulating film 233 is performed on the upper-layer side of the second semiconductor film 232, film formation of the third metal film is performed on the upper-layer side of the fourth insulating film 233, and the third metal film is patterned to provide the third gate electrode 227E disposed to overlap a part of the second semiconductor portion 227D, in patterning the second semiconductor film 232, film formation of the first photoresist film 221R1 is performed on the upper-layer side of the second semiconductor film 232, the first photoresist film 221R1 is exposed through the first photomask 21P1 and then the first photoresist film 221R1 is developed, and the second semiconductor film 232 is etched using the first photoresist film 221R1 as the mask to provide the second semiconductor portion 227D, in patterning the fourth insulating film 233, film formation of the fourth photoresist film (third photoresist film) 21R4 is performed on the upper-layer side of the fourth insulating film 233, the fourth photoresist film 21R4 is exposed through the second photomask 21P2 having the same pattern as the first photomask 21P1, and then the fourth photoresist film 21R4 is developed, and the fourth insulating film 233 is etched using the fourth photoresist film 21R4 as the mask. As described above, the pattern of the second photomask 21P2 used for the exposure of the fourth photoresist film 21R4 is the same as the pattern of the first photomask 21P1 used for the exposure of the first photoresist film 221R1, and thus the fourth insulating film 233 can be provided in the range overlapping the second semiconductor portion 227D. A photomask having a dedicated pattern for patterning the fourth insulating film 233 can be eliminated. The fourth insulating film 233 provided in this manner is disposed to overlap the second semiconductor portion 227D, and thus a part of the second contact hole 227CH1 is provided in the fourth insulating film 233 at the position overlapping the second semiconductor portion 227D. Thus, the first contact holes 215CH1 and 215CH2 are each provided in the two layers of the first insulating film 230 and the third insulating film 234, and the second contact hole 227CH1 is provided in the two layers of the fourth insulating film 233 and the third insulating film 234. As described above, the difference between the number of layers of the insulating films 230 and 234 each provided with the first contact holes 215CH1 and 215CH2 and the number of layers of the insulating films 233 and 234 each provided with the second contact hole 227CH1 can be eliminated. Accordingly, when the first contact holes 215CH1 and 215CH2 and the second contact hole 227CH1 are provided in the same step, a situation is much less likely to occur in which the second semiconductor portion 227D is over etched through the second contact hole 227CH1. Moreover, even when the residue of the second insulating film 231 is present at least in the range not overlapping the second semiconductor portion 227D, when the fourth insulating film 233 is patterned, the residue of the second insulating film 231 can be removed.

### Fourth Embodiment

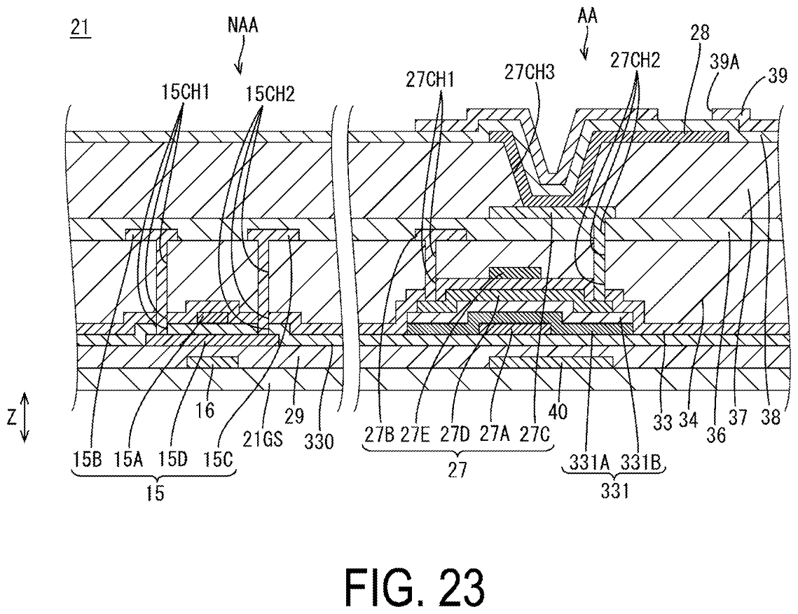

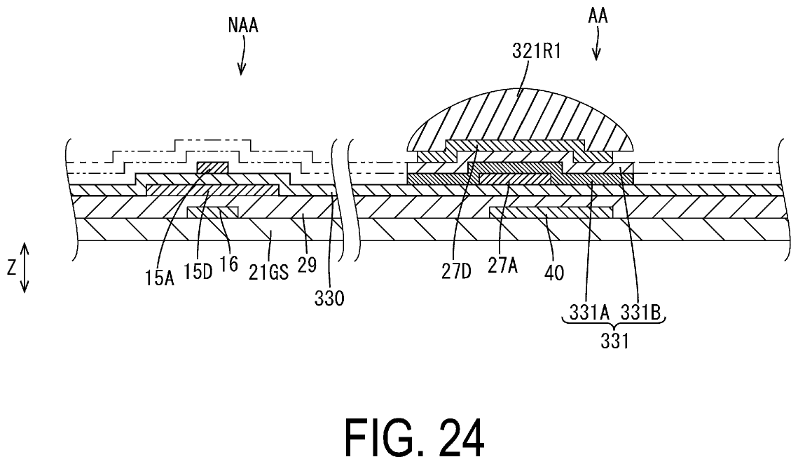

A fourth embodiment will be described with reference to FIG. 23 or FIG. 24. In the fourth embodiment, a case is described in which the first embodiment described above is changed to a configuration of a second insulating film 331. Further, repetitive descriptions of structures, actions, and effects similar to those of the first embodiment described above will be omitted.

As illustrated in FIG. 23, the second insulating film 331 according to the present embodiment has a layered structure of two layers including a lower layer film 331A and an upper layer film 331B made of materials different from each other. The lower layer film 331A is disposed on the upper-layer side of the first metal film. The lower layer film 331A is made of an inorganic material, for example, SiN. The film thickness of the lower layer film 331A is, for example, about 200 nm. The upper layer film 331B is disposed on the upper-layer side of the lower layer film 331A and on the lower-layer side of the second semiconductor film 32. The upper layer film 331B is made of an inorganic material, for example, SiO. The film thickness of the upper layer film 331B is, for example, about 100 nm.

In the sixth step, the lower layer film 331A, the upper layer film 331B, the second semiconductor film 32, and a first photoresist film 321R1 are continuously film-formed in this order on the upper-layer side of the first metal film. Thereafter, when the first photoresist film 321R1 is exposed and developed in the same manner as in the first embodiment, the first photoresist film 321R1 is patterned. The second semiconductor film 32 is wet etched through the patterned first photoresist film 321R1, and then the second insulating film 331 including the lower layer film 331A and the upper layer film 331B are dry etched. Thus, as illustrated in FIG. 24, the second semiconductor film 32 and the second insulating film 331 are each patterned. In the present embodiment, the first insulating film 330 is made of SiO, and the second insulating film 331 is a film in which the lower layer film 331A made of SiN having a film thickness of 200 nm and the upper layer film 331B made of SiO having a film thickness of 100 nm are sequentially layered. In such a configuration, films made of different materials are in contact with each other at the interface between the first insulating film 330 and the lower layer film 331A of the second insulating film 331. Thus, the selection ratio of the lower layer film 331A can be easily made larger than 1 when the lower layer film 331A of the second insulating film 331 is dry etched, and the overetching of the first insulating film 330 can be significantly reduced. At this time, the dry etching is performed using a gas such as carbon tetrafluoride (CF4), sulfur hexafluoride (SF6), chlorine, oxygen, and argon gases under a dry etching condition in which an appropriate selection ratio can be obtained.

### Fifth Embodiment

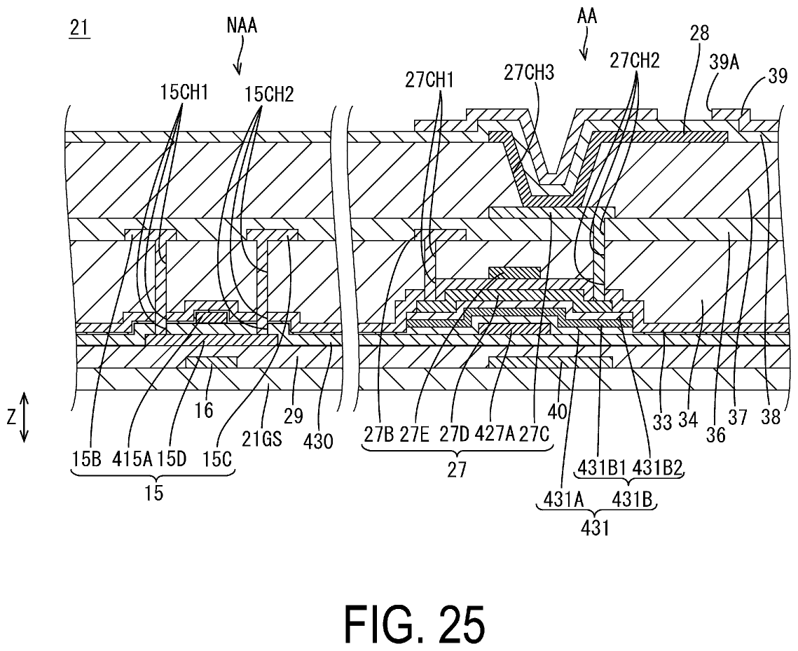

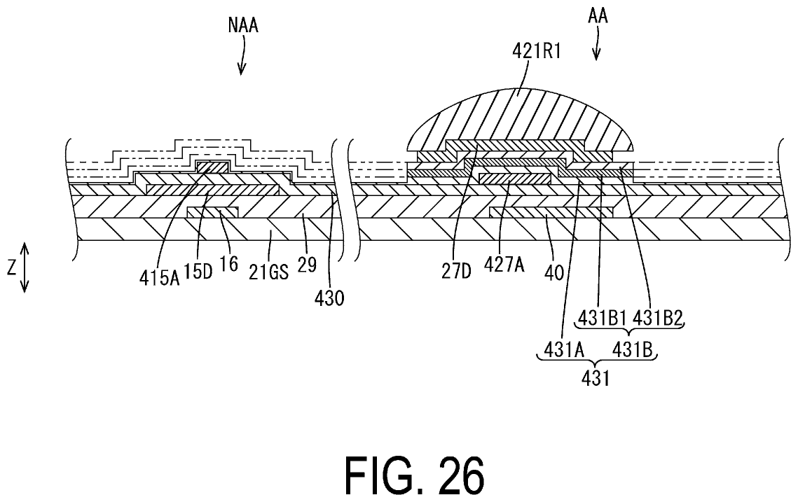

A fifth embodiment will be described with reference to FIG. 25 or FIG. 26. In the fifth embodiment, a case is described in which the fourth embodiment described above is changed to a configuration of a second insulating film 431. Further, repetitive descriptions of structures, actions, and effects similar to those of the fourth embodiment described above will be omitted.

As illustrated in FIG. 25, in the second insulating film 431 according to the present embodiment, an upper layer film 431B includes a first upper layer film 431B1 and a second upper layer film 431B2. That is, the second insulating film 431 has a layered structure of three layers including a lower layer film 431A, the first upper layer film 431B1, and the second upper layer film 431B2. The first upper layer film 431B1 is disposed on the upper-layer side of the lower layer film 431A and on the lower-layer side of the second upper layer film 431B2. That is, the first upper layer film 431B1 is located in the middle of the second insulating film 431. The first upper layer film 431B1 is made of an inorganic material, for example, SiN. The second upper layer film 431B2 is disposed on the upper-layer side of the first upper layer film 431B1. That is, the second upper layer film 431B2 is located as the uppermost layer of the second insulating film 431. The second upper layer film 431B2 is made of an inorganic material, for example, SiO.

In the present embodiment, the lower layer film 431A is made of the same inorganic material (material) as a first insulating film 430, and is made of, for example, SiO. The lower layer film 431A located as the lowermost layer in the second insulating film 431 is in contact with the first insulating film 430 in a portion of the second insulating film 431 not overlapping a first gate electrode 415A and a second gate electrodes 427A each made of the second metal film. When the second insulating film 431 is patterned in the sixth step, the etching depth may not reach the first insulating film 430, and a portion of the lower layer film 431A to be etched may remain. Even in this case, the residue of the lower layer film 431A is made of the same material as that of the first insulating film 430 and has a small difference in optical characteristics such as a refractive index, and thus an optical defect due to the residue of the lower layer film 431A is less likely to occur. Accordingly, the display defect (display unevenness) is less likely to occur. The lower layer film 431A is also made of the same inorganic material as the second upper layer film 431B2.

In the sixth step, the lower layer film 431A, the first upper layer film 431B1, the second upper layer film 431B2, the second semiconductor film 32, and the first photoresist film 421R1 are continuously film-formed in this order on the upper-layer side of the first metal film. Thereafter, when the first photoresist film 421R1 is exposed and developed in the same manner as in the first embodiment, the first photoresist film 421R1 is patterned. The second semiconductor film 32 is wet etched through the patterned first photoresist film 421R1, and then the second insulating film 431 including the lower layer film 431A, the first upper layer film 431B1, and the second upper layer film 431B2 are dry etched. Thus, as illustrated in FIG. 26, the second semiconductor film 32 and the second insulating film 431 are each patterned. When the second insulating film 431 is dry etched, the entire second insulating film 431 may not be removed, and the lower layer film 431A may slightly remain on the first insulating film 430. Even in this case, the residue of the lower layer film 431A remaining on the first insulating film 430 is made of the same material as that of the first insulating film 430, and thus a situation can be prevented in which light is refracted at the interface between the residue of the lower layer film 431A and the first insulating film 430. Accordingly, the display defect is less likely to occur.

As described above, according to the present embodiment, in performing film formation of the second insulating film 431, film formation of the lower layer film 431A made of the same material as the first insulating film 430 is performed on the upper-layer side of the second metal film, and film formation of the upper layer film 431B is performed on the upper-layer side of the lower layer film 431A to provide the second insulating film 431 having the layered structure. The portion of the second insulating film 431 provided in this manner not overlapping the second metal film (the first gate electrode 415A and the second gate electrode 427A) has a relationship in which the lower layer film 431A is in contact with the first insulating film 430. When the second insulating film 431 is patterned, the etching depth may not reach the first insulating film 430, and a portion of the lower layer film 431A to be etched may remain. Even in this case, the residue of the lower layer film 431A is made of the same material as that of the first insulating film 430 and has a small difference in optical characteristics such as the refractive index, and thus an optical defect due to the residue of the lower layer film 431A is less likely to occur. Accordingly, the display defect is less likely to occur.

### Sixth Embodiment

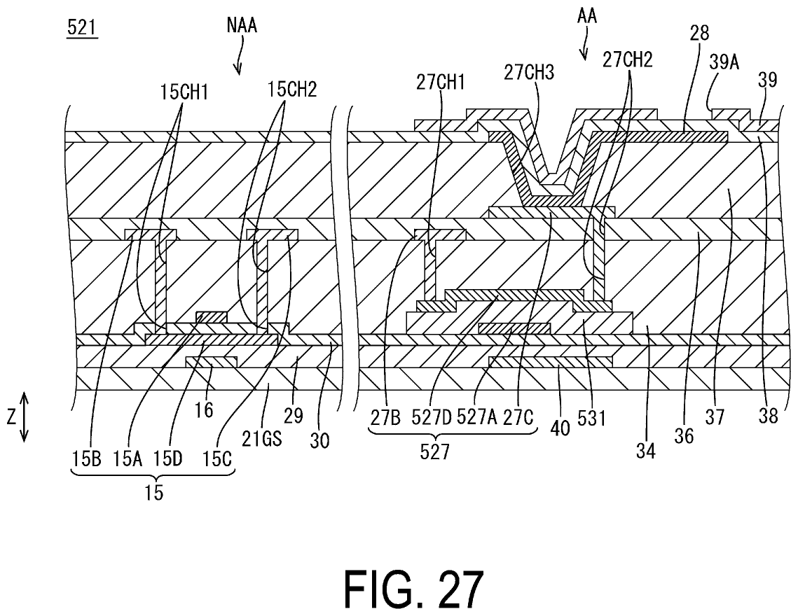

A six embodiment will be described with reference to FIG. 27. In the sixth embodiment, a case is described in which the first embodiment described above is changed to a configuration of a second TFT 527. Further, repetitive descriptions of structures, actions, and effects similar to those of the first embodiment described above will be omitted.

As illustrated in FIG. 27, the second TFT 527 according to the present embodiment has a bottom gate structure including a second gate electrode 527A disposed to overlap on a lower-layer side with respect to a second semiconductor portion 527D via a second insulating film 531. That is, the present embodiment is different from the first embodiment in that the second TFT 527 does not include the third gate electrode 27E (see FIG. 6). With this change, an array substrate 521 according to the present embodiment does not include the third metal film and the fourth insulating film 33 (see FIG. 6) described in the first embodiment. In the present embodiment, the same actions and effects as those of the first embodiment can be obtained except that the channel region is generated in the second semiconductor portion 527D due to the electrical field from only the second gate electrode 527A in the second TFT 527.

### Seventh Embodiment

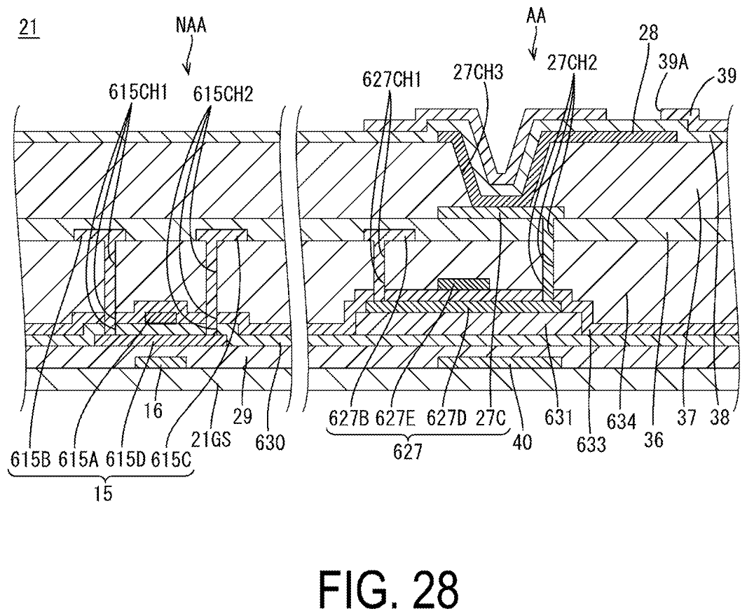

A seventh embodiment will be described with reference to FIG. 28. In the seventh embodiment, a case is described in which the first embodiment described above is changed to a configuration of a second TFT 627. Further, repetitive descriptions of structures, actions, and effects similar to those of the first embodiment described above will be omitted.

As illustrated in FIG. 28, the second TFT 627 according to the present embodiment has a top gate structure including a third gate electrode 627E disposed to overlap on an upper-layer side with respect to a second semiconductor portion 627D via a fourth insulating film 633. That is, the present embodiment is different from the first embodiment in that the second TFT 627 does not include the second gate electrode 27A (see FIG. 6). In the present embodiment, the same actions and effects as those of the first embodiment can be obtained except that the channel region is generated in the second semiconductor portion 627D due to the electrical field from only the third gate electrode 627E in the second TFT 627.

As described above, the liquid crystal panel 11 of the present embodiment includes the first semiconductor portion 615D made of the first semiconductor film, the first insulating film 630 disposed on the upper-layer side of the first semiconductor film, the first gate electrode 615A made of the second metal film (first conductive film) disposed on the upper-layer side of the first insulating film 630 and disposed to overlap a part of the first semiconductor portion 615D, the second insulating film 631 disposed on the upper-layer side of the second metal film, the second semiconductor portion 627D made of the second semiconductor film 32 (see FIG. 8) disposed on the upper-layer side of the second insulating film 631, the fourth insulating film (third insulating film) 633 disposed on the upper-layer side of the second semiconductor film 32, the third gate electrode (second electrode) 627E made of the third metal film (second conductive film) disposed on the upper-layer side of the fourth insulating film 633 and disposed to overlap a part of the second semiconductor portion 627D, the third insulating film (fourth insulating film) 634 disposed on the upper-layer side of the third metal film, the first source electrode 615B and first drain electrode 615C (third electrodes) made of the fourth metal film (third conductive film) 35 (see FIG. 13) disposed on the upper-layer side of the third insulating film 634 and disposed at the position overlapping the first semiconductor portion 615D and not overlapping the first gate electrode 615A, and the second source electrode (fourth electrode) 627B made of a part of the fourth metal film 35 different from the first source electrode 615B and the first drain electrode 615C and disposed at the position overlapping the second semiconductor portion 627D and not overlapping the third gate electrode 627E. The second insulating film 631 is disposed to overlap at least the second semiconductor portion 627D and is not formed in the range overlapping the first semiconductor portion 615D, the fourth insulating film 633 is disposed to overlap at least the third gate electrode 627E, the first contact holes 615CH1 and 615CH2 connecting the first source electrode 615B and the first drain electrode 615C, respectively, to the first semiconductor portion 615D is provided in the first insulating film 630 and the third insulating film 634 at the positions overlapping the first semiconductor portion 615D, the first source electrode 615B, and the first drain electrode 615C, and the second contact hole 627CH1 connecting the second source electrode 627B to the second semiconductor portion 627D is provided in the third insulating film 634 at the position overlapping the second semiconductor portion 627D and the second source electrode 627B.

The first insulating film 630 is interposed between the first gate electrode 615A and the first semiconductor portion 615D, and thus the channel region can be generated in the first semiconductor portion 615D due to a voltage applied to the first gate electrode 615A. The fourth insulating film 633 is interposed between the third gate electrode 627E and the second semiconductor portion 627D, and thus the channel region can be generated in the second semiconductor portion 627D due to a voltage applied to the third gate electrode 627E.

The first source electrode 615B, the first drain electrode 615C, and the second source electrode 627B are all made of the fourth metal film 35, and thus the number of layers of the conductive film can be reduced as compared with the case where the first source electrode, the first drain electrode, and the second source electrode are made of different conductive films, respectively. In addition, before the film formation of the fourth metal film 35, the first contact holes 615CH1 and 615CH2 and the second contact hole 627CH1 can be provided in the third insulating film 634 and the like in the same step. Thus, the tact can be shortened.

The second insulating film 631 is disposed to overlap at least the second semiconductor portion 627D and is not formed in the range overlapping the first semiconductor portion 615D, and thus the first contact holes 615CH1 and 615CH2 are not provided in the second insulating film 631 but are each provided in at least the two layers of the first insulating film 630 and the third insulating film 634. When the second insulating film is also present in a range overlapping the first semiconductor portion 615D, the first contact holes are each provided over at least the three layers of the first insulating film 630, the second insulating film 631, and the third insulating film 634. As described above, the second insulating film 631 is not formed in the range overlapping the first semiconductor portion 615D, and thus the number of layers of the insulating films 630, 633, and 634 each provided with the first contact holes 615CH1 and 615CH2 can be reduced. Thus, the difference between the number of layers of the insulating films 630, 633, and 634 each provided with the first contact holes 615CH1 and 615CH2 and the number of layers of the insulating films 633 and 634 each provided with the second contact hole 627CH1 becomes smaller. Accordingly, when the first contact holes 615CH1 and 615CH2 and the second contact hole 627CH1 are provided in the same step, a situation is less likely to occur in which the second semiconductor portion 627D is over etched through the second contact hole 627CH1.

### OTHER EMBODIMENTS

The technology disclosed herein are not limited to the embodiments described above and illustrated in the drawings, and the following embodiments, for example, are also included within the technical scope.
(1) The formation ranges of the second insulating films 31, 131, 231, 331, 431, 531, and 631 can be each appropriately changed to a respective one of formation ranges other than those illustrated in the drawings. For example, the second insulating films 31, 131, 231, 331, 431, 531, and 631 may be disposed to be solid-like in the display region AA and may not be formed in the non-display region NAA. The second insulating films 31, 131, 231, 331, 431, 531, and 631 may be each provided in a range not overlapping a respective one of the first semiconductor portions 15D, 115D, and 615D in the non-display region NAA. In short, the specific formation range of each of the second insulating films 31, 131, 231, 331, 431, 531, and 631 can be appropriately changed as long as it is not formed in the range overlapping the respective one of the first semiconductor portions 15D, 115D, and 615D.
(2) In the second embodiment, the outer edge of the fourth insulating film 133 and the outer edge of the third gate electrode 127E may be disposed to be not aligned with each other (disposed similarly in the first and third embodiments). After the third metal film 41 is wet etched in the eighth step, the fourth insulating film 133 may be dry etched and patterned.
(3) In the second embodiment, after the third metal film 41 is patterned, the fourth insulating film 133 may be patterned using a dedicated photomask and a photoresist film.
(4) In third embodiment, the outer edge of the fourth insulating film 233 and the outer edge of the third gate electrode 227E may be disposed to be substantially aligned with each other. In the eighth step, the third metal film and the fourth insulating film 233 may be patterned together by dry etching.
(5) In the third embodiment, after patterning the third metal film, the fourth insulating film 233 may be patterned using a dedicated photomask and a photoresist film having a pattern different from that of the first photomask used for patterning the second semiconductor films 32 and 232.
(6) In the fourth embodiment, the material of the upper layer film 331B may be SiN, and the material of the lower layer film 331A may be SiO. In this case, the materials of the lower layer film 331A and the first insulating film 330 are the same, and thus the same actions and effects as those of the fifth embodiment can be obtained.
(7) In the fourth embodiment, the material of the first insulating film 330 may be SiN. In this case, the materials of the lower layer film 331A and the first insulating film 330 are the same, and thus the same actions and effects as those of the fifth embodiment can be obtained.
(8) In the fourth embodiment, specific materials used for the lower layer film 331A, the upper layer film 331B, and the first insulating film 330 may be each appropriately changed to a respective one of materials other than SiN and SiO.
(9) In the fifth embodiment, the material of the first upper layer film 431B1 may be SiO, the material of the lower layer film 431A and the second upper layer film 431B2 may be SiN, and the material of the first insulating film 430 may be SiN.
(10) In the fifth embodiment, specific materials used for the lower layer film 431A, the first upper layer film 431B1, the second upper layer film 431B2, and the first insulating film 430 can be each appropriately changed to a respective one of materials other than SiN and SiO.
(11) A part of each of the first source electrode 15B and 615B may overlap a respective one of the first gate electrode 15A, 415A, and 615A. Similarly, a part of each of the first drain electrode 15C and 615C may overlap a respective one of the first gate electrode 15A, 415A, and 615A. Similarly, a part of each of the second source electrodes 27B and 627B may overlap at least one of a respective one of the second gate electrodes 27A, 127A, 227A, 427A, and 527A and a respective one of the third gate electrodes 27E, 127E, and 227E. The second drain electrode 27C may be disposed not to overlap at least one of a respective one of the second gate electrode 27A, 127A, 227A, 427A, and 527A and a respective one of the third gate electrode 27E, 127E, and 227E.
(12) The first source electrodes 15B and 615B or the first drain electrodes 15C and 615C may be made of the fifth metal film. In this case, the first source electrodes 15B and 615B or the first drain electrodes 15C and 615C made of the fifth metal film are each connected to a respective one of the first semiconductor portions 15D, 115D, and 615D through the fifth contact holes provided in a respective one of the first insulating film 30, 130, 230, 330, 430, and 630, a respective one of the third insulating films 34, 134, 234, and 634, a respective one of the fourth insulating films 33, 133, 233, and 633, and the fifth insulating film 36.
(13) The second drain electrode 27C may be made of the same fourth metal film 35 as the second source electrodes 27B and 627B. In this case, the fifth metal film and the fifth insulating film 36 may be omitted. The fifth metal film and the sixth insulating film 37 can be also omitted and the fourth contact hole 27CH3 can be provided in the fifth insulating film 36.
(14) A photosensitive resin material can be also used as the material of the third insulating films 34, 134, 234, and 634. In this way, the third insulating films 34, 134, 234, and 634 can be patterned without using the photoresist film. Similarly, the photosensitive resin material can be also used as the material of the sixth insulating film 37.
(15) Each of the photoresist films 21R1 to 21R4 may be the positive-working photosensitive resist material, but a negative-working photosensitive resist material may be also used.
(16) As the conductive film used for the array substrates 21, 121, 221, and 521, a low resistive film obtained by subjecting a semiconductor film to a low resistive treatment can be used other than the metal film. A transparent electrode film can be also used as the conductive film.
(17) A part or the entirety of at least one of the first circuit portion 14A and the second circuit portion 14B may be disposed in the display region AA.
(18) At least one of the first light blocking portion 16 and the second light blocking portion 40 may be omitted. When both the first light blocking portion 16 and the second light blocking portion 40 are omitted together, the first metal film can be omitted.
(19) The materials of the substrates 20GS and 21GS may be synthetic resins or the like other than glass.
(20) The specific numerical value of the pixel density of the liquid crystal panel 11 can be changed as appropriate.
(21) The display mode of the liquid crystal panel 11 may be an IPS mode or the like.
(22) The planar shape of the liquid crystal panel 11 may be rectangular with horizontal elongation, rectangular with vertical elongation, square, circular, semi-circular, elliptical, oval, trapezoidal, or the like.
(23) The configurations described in the fourth and fifth embodiments can be also combined with the configurations described in the second, third, sixth, and seventh embodiments as appropriate. In addition, the configuration described in the respective embodiments can be combined as appropriate.
(24) Other than the liquid crystal panel 11, an organic EL display device which is a self-luminous display device may be used.
(25) In addition to the head-mounted display 10HMD, the present disclosure can be applied to, for example, a head-up display, a projector, or the like as a device that enlarges and displays an image displayed on the liquid crystal panel 11 using a lens or the like. The present disclosure can be also applied to a display device that does not have an enlarged display function (a television receiver, a tablet terminal, a smartphone, or the like).

While preferred embodiments of the present invention have been described above, it is to be understood that variations and modifications will be apparent to those skilled in the art without departing from the scope and spirit of the present invention. The scope of the present invention, therefore, is to be determined solely by the following claims.

1. A display device comprising:
a first semiconductor portion made of a first semiconductor film;
a first insulating film disposed on an upper-layer side of the first semiconductor film;
a first electrode made of a first conductive film disposed on an upper-layer side of the first insulating film and disposed to overlap a part of the first semiconductor portion;
a second electrode made of a part of the first conductive film, the part being different from the first electrode;
a second insulating film disposed on an upper-layer side of the first conductive film;
a second semiconductor portion made of a second semiconductor film disposed on an upper-layer side of the second insulating film, including a part disposed to overlap the second electrode;
a third insulating film disposed on an upper-layer side than the second semiconductor film;
a third electrode made of a second conductive film disposed on an upper-layer side of the third insulating film and disposed at a position overlapping the first semiconductor portion and not overlapping the first electrode; and
a fourth electrode made of a part of the second conductive film, the part being different from the third electrode, and disposed to overlap a part of the second semiconductor portion,
wherein the second insulating film is disposed to overlap at least the second semiconductor portion and is not formed in a range overlapping the first semiconductor portion,
a first contact hole connecting the third electrode to the first semiconductor portion is provided in the first insulating film and the third insulating film at a position overlapping the first semiconductor portion and the third electrode, and
a second contact hole connecting the fourth electrode to the second semiconductor portion is provided in the third insulating film at a position overlapping the second semiconductor portion and the fourth electrode.

2. The display device according to claim 1 further comprising:
a fourth insulating film disposed on an upper-layer side of the second semiconductor film and on a lower-layer side than the third insulating film; and
a fifth electrode made of a third conductive film disposed on an upper-layer side of the fourth insulating film and on a lower-layer side of the third insulating film and disposed to overlap a part of the second semiconductor portion,
wherein the fifth electrode is connected to the second electrode.

3. The display device according to claim 2,
wherein the fourth insulating film is disposed to overlap at least each of the first semiconductor portion and the second semiconductor portion, and
a part of the first contact hole and a part of the second contact hole are provided in the fourth insulating film.

4. The display device according to claim 2,
wherein the fourth insulating film is disposed to overlap the fifth electrode or the second semiconductor portion.

5. The display device according to claim 4,
wherein the fourth insulating film is disposed to overlap the fifth electrode.

6. The display device according to claim 4,
wherein the fourth insulating film is disposed to overlap the second semiconductor portion, and
a part of the second contact hole is provided in the fourth insulating film at a position overlapping the second semiconductor portion.

7. The display device according to claim 1 further comprising:
a pixel electrode;
a display region, the pixel electrode being disposed and an image being displayed in the display region;
a sixth electrode disposed in the display region and connected to the pixel electrode;
a first wiring line disposed in the display region;
a second wiring line disposed in the display region; and
a circuit portion supplying a signal to at least one of the first wiring line and the second wiring line,
wherein the first semiconductor film is made of a polysilicon semiconductor material,
the second semiconductor film is made of an oxide semiconductor material,
the first semiconductor portion, the first electrode, and the third electrode are disposed in the circuit portion,
the second semiconductor portion, the second electrode, and the fourth electrode are disposed in the display region,
the second electrode is connected to the first wiring line,
the fourth electrode is connected to the second wiring line, and
the sixth electrode is connected to the second semiconductor portion.

8. A display device comprising:
a first semiconductor portion made of a first semiconductor film;
a first insulating film disposed on an upper-layer side of the first semiconductor film;
a first electrode made of a first conductive film disposed on an upper-layer side of the first insulating film and disposed to overlap a part of the first semiconductor portion;
a second insulating film disposed on an upper-layer side of the first conductive film;
a second semiconductor portion made of a second semiconductor film disposed on an upper-layer side of the second insulating film;
a third insulating film disposed on an upper-layer side of the second semiconductor film;
a second electrode made of a second conductive film disposed on an upper-layer side of the third insulating film and disposed to overlap a part of the second semiconductor portion;
a fourth insulating film disposed on an upper-layer side of the second conductive film;
a third electrode made of a third conductive film disposed on an upper-layer side of the fourth insulating film and disposed at a position overlapping the first semiconductor portion and not overlapping the first electrode; and
a fourth electrode made of a part of the third conductive film different from the third electrode and disposed at a position overlapping the second semiconductor portion and not overlapping the second electrode,
wherein the second insulating film is disposed to overlap at least the second semiconductor portion and is not formed in a range overlapping the first semiconductor portion,
the third insulating film is disposed to overlap at least the second electrode,
a first contact hole connecting the third electrode to the first semiconductor portion is provided in the first insulating film and the third insulating film at a position overlapping the first semiconductor portion and the fourth electrode, and
a second contact hole connecting the fourth electrode to the second semiconductor portion is provided in the fourth insulating film at a position overlapping the second semiconductor portion and the fourth electrode.

9. A manufacturing method of a display device, the manufacturing method comprising:
performing film formation of a first semiconductor film and patterning the first semiconductor film to provide a first semiconductor portion;
performing film formation of a first insulating film on an upper-layer side of the first semiconductor film:
performing film formation of a first conductive film on an upper-layer side of the first insulating film and patterning the first conductive film to provide a first electrode and a second electrode disposed to overlap a part of the first semiconductor portion;
performing film formation of a second insulating film on an upper-layer side of the first conductive film;
performing film formation of a second semiconductor film on an upper-layer side of the second insulating film and patterning the second semiconductor film to provide a second semiconductor portion including a part disposed to overlap the second electrode;
patterning the second insulating film to overlap at least the second semiconductor portion and not being formed in a range overlapping the first semiconductor portion;
performing film formation of a third insulating film on an upper-layer side than the second semiconductor film and patterning the third insulating film to provide a part of a first contact hole at a position overlapping a part of the first semiconductor portion and not overlapping the first electrode and to provide a second contact hole at a position overlapping a part of the second semiconductor portion;
patterning the first insulating film subsequent to the third insulating film to provide a part of the first contact hole at a position overlapping a part of the first semiconductor portion and not overlapping the first electrode; and
performing film formation of a second conductive film on an upper-layer side of the third insulating film and patterning the second conductive film to provide a third electrode disposed to overlap the first contact hole and connected to the first semiconductor portion through the first contact hole and a fourth electrode disposed to overlap the second contact hole and connected to the second semiconductor portion through the second contact hole.

10. The manufacturing method of a display device according to claim 9,
wherein, in patterning the second semiconductor film, film formation of a first photoresist film is performed on an upper-layer side of the second semiconductor film, the first photoresist film is exposed and developed, and then the second semiconductor film is etched using the first photoresist film as a mask to provide the second semiconductor portion, and
in patterning the second insulating film, the second insulating film is etched using the first photoresist film as a mask.

11. The manufacturing method of a display device according to claim 10,
wherein, in patterning the second semiconductor film, the second semiconductor film is wet etched, and
in patterning the second insulating film, the second insulating film is dry etched.

12. The manufacturing method of a display device according to claim 10,
wherein, in patterning the second insulating film, an etching rate of the second insulating film is set higher than an etching rate of the first insulating film.

13. The manufacturing method of a display device according to claim 10,
wherein, in performing film formation of the second insulating film, film formation of a lower layer film made of the same material as the first insulating film is performed on an upper-layer side of the first conductive film, and film formation of an upper layer film is performed on an upper-layer side of the lower layer film to provide the second insulating film having a layered structure.

14. The manufacturing method of a display device according to claim 9,
wherein, before performing film formation of the third insulating film, film formation of a fourth insulating film is performed on an upper-layer side of the second semiconductor film, film formation of a third conductive film is performed on an upper-layer side of the fourth insulating film, and the third conductive film is patterned to provide a fifth electrode disposed to overlap a part of the second semiconductor portion,
in patterning the third conductive film, film formation of a second photoresist film is performed on an upper-layer side of the third conductive film, the second photoresist film is exposed and developed, and then the third conductive film is etched using the second photoresist film as a mask to provide the fifth electrode, and
in patterning the fourth insulating film,
the fourth insulating film is etched using the second photoresist film as a mask.

15. The manufacturing method of a display device according to claim 9,
wherein, before performing film formation of the third insulating film, film formation of a fourth insulating film is performed on an upper-layer side of the second semiconductor film, film formation of a third conductive film is performed on an upper-layer side of the fourth insulating film, and the third conductive film is patterned to provide a fifth electrode disposed to overlap a part of the second semiconductor portion,
in patterning the second semiconductor film, film formation of a first photoresist film is performed on an upper-layer side of the second semiconductor film, the first photoresist film is exposed through a first photomask, and then the first photoresist film is developed, and the second semiconductor film is etched using the first photoresist film as a mask to provide the second semiconductor portion, and
in patterning the fourth insulating film, film formation of a third photoresist film is performed on an upper-layer side of the fourth insulating film, the third photoresist film is exposed through a second photomask having the same pattern as a pattern of the first photomask, and then the third photoresist film is developed, and the fourth insulating film is etched using the third photoresist film as a mask.
